(19) United States
(12) Patent Application Publication
(10) Pub. No.: US 2024/0039243 A1
(43) Pub. Date: Feb. 1, 2024

(54) Etalon, Etalon Device, Method for Controlling Etalon, and Method for Determining Refractive Index

(71) Applicant: Nippon Telegraph and Telephone Corporation, Tokyo (JP)

(72) Inventors: Masahiro Ueno, Musashino-shi, Tokyo (JP); Yurina Tanaka, Musashino-shi, Tokyo (JP); Sohan Kawamura, Musashino-shi, Tokyo (JP); Yuichi Akage, Musashino-shi, Tokyo (JP); Takashi Sakamoto, Musashino-shi, Tokyo (JP); Soichi Oka, Musashino-shi, Tokyo (JP)

(21) Appl. No.: 18/041,247

(22) PCT Filed: Sep. 7, 2020
(86) PCT No.: PCT/JP2020/033788

§ 371 Date: Feb. 10, 2023

(51) Int. Cl. H01S 5/14; H01S 5/06

(52) U.S. Cl. CPC H01S 5/141; H01S 5/0612

(57) ABSTRACT

An etalon according to the present invention is an etalon in which light is made incident from a direction different from a direction perpendicular to an incident surface and is emitted from an emission surface facing the incident surface, the etalon comprising a dielectric that has a first end surface on the incident surface side and a second end surface on the emission surface side so as to oppose the first end surface, wherein a refractive index distribution of the dielectric is set in such a manner that a lateral shift of the light becomes smaller between the first end surface and the second end surface as compared with a uniform refractive index distribution etalon under a condition that an optical path length of the light is equal. Therefore, the light according to the present invention can provide excellent wavelength controllability.

### TECHNICAL FIELD

The present invention relates to an etalon, an etalon device, an etalon control method, and a refractive index determination method.

### BACKGROUND ART

An etalon as an optical element is used as an optical filter in the field of wavelength multiplexing (WDM) transmission optical communication, precision measurement, and the like, such as a wavelength selection filter or an interference filter for narrowing a wavelength band. A laser beam is made incident on the etalon, and wavelength-selected light or wavelength-narrowed light is emitted. An ordinary etalon has a uniform refractive index, and operates by using interference of light between an incident surface and an emission surface (reflection surface) (NPL 1).

In a case where an etalon is inserted so as to pass through an optical axis in a laser resonator in order to select a resonance wavelength, when an incident angle of light to the etalon (an angle formed by the optical axis and a normal vector of an etalon incident surface) is set to 0 degrees, an unnecessary resonator is formed by reflected light from the incident surface of the etalon, resulting in an undesirable laser oscillation wavelength.

Therefore, it is usually necessary to make light incident at a predetermined angle without setting the incident angle to the etalon to 0 degrees.

### CITATION LIST

### Non Patent Literature

[NPL 1] Pierre Jacquinot, “The Luminosity of Spectrometers with Prisms, Gratings, or Fabry-Perot Etalons,” Journal of the Optical Society of America, Vol. 44, Issue 10, pp. 761-765, 1954.

### SUMMARY OF INVENTION

### Technical Problem

However, when the incident angle is too large, the optical axis becomes shifted due to the lateral shift of the beam of light multiply reflected inside the etalon, and the wavelength controllability is impaired due to the change of the optical path length in the laser resonator. In order to suppress the loss of the wavelength controllability, it is necessary to finely adjust the arrangement of the optical components in the laser resonator, which requires labor, time and cost. Therefore, it is necessary to suppress the lateral shift of the beam of the light multiply reflected inside the etalon, and to suppress the loss of wavelength stability and controllability of the etalon.

### Solution to Problem

In order to solve the problems described above, an etalon according to the present invention is an etalon in which light is made incident from a direction different from a direction perpendicular to an incident surface and is emitted from an emission surface facing the incident surface, the etalon including a dielectric that has a first end surface on the incident surface side and a second end surface on the emission surface side so as to oppose the first end surface, wherein a refractive index distribution of the dielectric is set in such a manner that a lateral shift of the light becomes smaller between the first end surface and the second end surface as compared with a uniform refractive index distribution etalon under a condition that an optical path length of the light is equal.

The etalon according to the present invention is an etalon in which light is made incident from a direction different from a direction perpendicular to an incident surface and is emitted from an emission surface facing the incident surface, the etalon including a dielectric that has a first end surface on the incident surface side and a second end surface on the emission surface side so as to oppose the first end surface, wherein a refractive index of the dielectric changes by a quadratic function of x when a distance in a vertical direction from the first end surface toward the second end surface is x.

The etalon according to the present invention is an etalon in which light is made incident from a direction different from a direction perpendicular to an incident surface and is emitted from an emission surface facing the incident surface, the etalon including a dielectric that has a first end surface on the incident surface side and a second end surface on the emission surface side so as to oppose the first end surface, wherein a refractive index of the dielectric changes from the first end surface toward the second end surface by voltage application.

An etalon control method according to the present invention is a method for controlling an etalon in which light is made incident from a direction different from a direction perpendicular to an incident surface and is emitted from an emission surface facing the incident surface, the etalon including a dielectric having a first end surface on the incident surface side and a second end surface on the emission surface side so as to oppose the first end surface, wherein the method includes the steps of: applying a voltage between the first end surface and the second end surface to change a refractive index of the dielectric between the first end surface and the second end surface; and reducing a distance between a point on the emission surface from which the light is emitted and a point on the emission surface where the light is incident from the direction perpendicular to the incident surface and emitted.

A refractive index determination method according to the present invention is a method for determining a refractive index of a first dielectric in a first etalon in which light is made incident from a direction different from a direction perpendicular to an incident surface and is emitted from an emission surface facing the incident surface, the method comprising the steps of: converting a refractive index of a second dielectric of a second etalon having a uniform refractive index distribution in such a manner that an optical path length of the second etalon and an optical path length of the first etalon are equal to each other; deriving a lateral shift of the second etalon using the converted refractive index; deriving a lateral shift of the first etalon; comparing the lateral shift of the first etalon with the lateral shift of the second etalon; and deriving the refractive index of the first dielectric in such a manner that the lateral shift of the first etalon is smaller than the lateral shift of the second etalon.

### Advantageous Effects of Invention

According to the present invention, an etalon, an etalon device, an etalon control method, and a refractive index determination method, which are excellent in wavelength controllability, can be provided.

### BRIEF DESCRIPTION OF DRAWINGS

FIG. 1 is a side conceptual diagram of an etalon according to a first embodiment of the present invention and a diagram showing a refractive index distribution of the etalon.

FIG. 2 is a side conceptual diagram of an etalon having a uniform refractive index distribution and a diagram showing a refractive index distribution of the etalon.

FIG. 3A is a diagram for explaining effects of the etalon according to the first embodiment of the present invention.

FIG. 3B is a diagram for explaining effects of the etalon according to the first embodiment of the present invention.

FIG. 3C is a diagram for explaining effects of the etalon according to the first embodiment of the present invention.

FIG. 3D is a diagram for explaining effects of the etalon according to the first embodiment of the present invention.

FIG. 4A is a diagram for explaining effects of the etalon according to the first embodiment of the present invention.

FIG. 4B is a diagram for explaining effects of the etalon according to the first embodiment of the present invention.

FIG. 5A is a side conceptual diagram showing a configuration of an etalon according to a second embodiment of the present invention.

FIG. 5B is a perspective view showing the configuration of the etalon according to the second embodiment of the present invention.

FIG. 5C is a side conceptual diagram showing a configuration of an etalon according to a third embodiment of the present invention.

FIG. 5D is a transparent perspective view showing the configuration of the etalon according to the third embodiment of the present invention.

FIG. 5E is a side sectional schematic view of a configuration of an etalon according to a fourth embodiment of the present invention.

FIG. 6 is a diagram for explaining operations of the etalons according to the second to fourth embodiments of the present invention.

FIG. 7A is a diagram for explaining effects of the etalons according to the second to fourth embodiments of the present invention.

FIG. 7B is a diagram for explaining the effects of the etalons according to the second to fourth embodiments of the present invention.

FIG. 7C is a diagram for explaining the effects of the etalons according to the second to fourth embodiments of the present invention.

FIG. 7D is a diagram for explaining the effects of the etalons according to the second to fourth embodiments of the present invention.

FIG. 8 is a table for illustrating the effects of the etalons according to the second to fourth embodiments of the present invention.

FIG. 9A is a diagram for explaining the effects of the etalons according to the second to fourth embodiments of the present invention.

FIG. 9B is a diagram for explaining the effects of the etalons according to the second to fourth embodiments of the present invention.

FIG. 9C is a diagram for explaining the effects of the etalons according to the second to fourth embodiments of the present invention.

FIG. 9D is a diagram for explaining the effects of the etalons according to the second to fourth embodiments of the present invention.

FIG. 10A is a diagram for explaining the effects of the etalons according to the second to fourth embodiments of the present invention.

FIG. 10B is a diagram for explaining the effects of the etalons according to the second to fourth embodiments of the present invention.

FIG. 10C is a diagram for explaining the effects of the etalons according to the second to fourth embodiments of the present invention.

FIG. 11 is a schematic view showing a configuration of an etalon device according to a fifth embodiment of the present invention.

### DESCRIPTION OF EMBODIMENTS

### First Embodiment

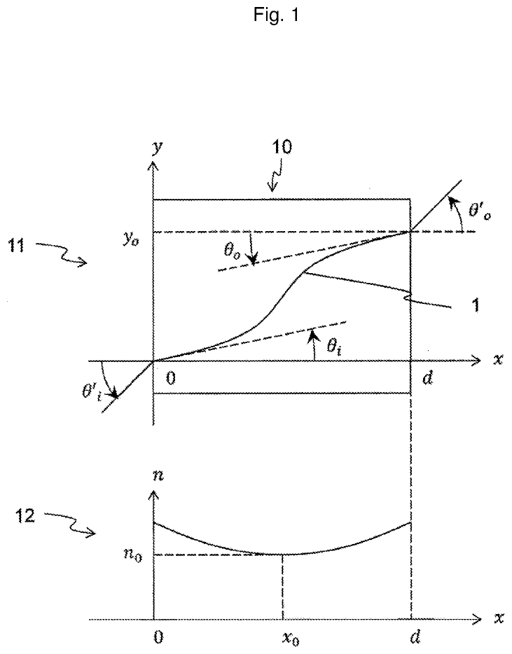

An etalon according to a first embodiment of the present invention will be described with reference to FIGS. 1 to 4B.

An etalon 10 according to the present embodiment suppresses a lateral shift of light transmitted through the etalon, by changing the refractive index of a dielectric used in the etalon. Here, “lateral shift” means a distance between an intersection of a line passing through an incident point on an incident surface of the etalon and perpendicular to the incident surface and an emission surface, and an emission point on the emission surface when light is incident on the incident surface at a predetermined angle (without including a direction perpendicular to the incident surface) and is emitted from the emission surface.

Here, the distribution of the refractive index of the dielectric is set in such a manner that, when the lateral shift of the etalon 10 whose refractive index changes is compared with the lateral shift of an etalon whose refractive index is uniform (“uniform refractive index distribution etalon,” hereinafter), the lateral shift of the etalon 10 is smaller than the lateral shift of the uniform refractive index distribution etalon.

In so doing, the distribution of the refractive index of the dielectric is set in such a manner that the optical path of light transmitted through the etalon becomes equivalent between the etalon 10 and the uniform refractive index distribution etalon. The lateral shift of the etalon 10 and the lateral shift of the uniform refractive index distribution etalon are expressed by an incident angle from the outside of light transmitted through the etalon.

In the present embodiment, a case where the refractive index changes by a quadratic function of a distance X in the direction perpendicular to the incident surface will be described in detail as an example of the refractive index distribution of the dielectric of the etalon 10.

FIG. 1 shows a side conceptual diagram 11 and a refractive index distribution 12 of the etalon 10 according to the first embodiment. An upper conceptual diagram 11 shows an optical path 1 of light incident on the etalon 10.

The etalon 10 is provided with a material for transmitting light (dielectric), and a semi-reflective film formed on a surface where the light enters and exits. The refractive index inside the etalon 10 varies in relation to an x-axis direction and does not vary in relation to a y-axis direction and is constant. The refractive index n inside the etalon 10 is represented by a quadratic function of x, as shown in the expression (1).

Math. 1

n=n₀[1+β(x−x₀)²] (1)

Here, n₀ is the minimum value of n, and x₀ represents the position in the x-axis direction where n is the minimum value. β is a coefficient of the refractive index distribution (referred to as “refractive index coefficient,” hereinafter), and is a positive real number.

For reference, an expression generally used for defining a lens is shown below.

Math. 2

n=nₒ[1−B·(x−x₀)²] (1′)

Here, B is a convergence coefficient. When parallel light is transmitted in the y-axis direction when B>O, the etalon 10 becomes a convex lens having the maximum refractive index at x₀, and converges (focuses) the parallel light traveling in the y-axis direction. The refractive index distribution constants √A and B used in the refractive index distribution type (Graded-Index, GRIN) lens are in the relation shown by the expression (2). where B>0.

$$\begin{matrix}Math . 3 & \\ B = \frac{{( \sqrt{A} )}^{2}}{2} & ( 2 )\end{matrix}$$

First, the optical path length of the light transmitted through the etalon 10 will be described. The optical path length L inside the etalon 10 shown in FIG. 1 is expressed by the expression (3).

$$\begin{matrix}Math . 4 & \\ L = {\int }_{{s}_{1}}^{{s}_{2}} n ds & ( 3 )\end{matrix}$$

The linear element ds in the expression (3) is expressed by the expression (4).

$$\begin{matrix}Math . 5 & \\ ds = \sqrt{{( dx )}^{2} + {( dy )}^{2}} = \sqrt{1 + {( \frac{dy}{dx} )}^{2}} & ( 6 )\end{matrix}$$

$$dx = \sqrt{1 + {( {y}^{′} )}^{2}} dx \text{?}$$

$$\text{?} \text{indicates text missing or illegible when filed}$$

Here, y′=dy/dx. The expression (5) is obtained because the expressions (3) and (4) and the integral range in the x-axis direction are 0 to d. Here, d represents the thickness of the etalon.

### Embodiment 2

Math. 6

L=∫₀^{d}n·\sqrt{1+(y′)²}dx (5)

When g=n√(1+y′²), from Fermat's principle, g is a function that minimizes the optical path length L. Since g is a function of x, y and y′, it is known that the function g, which minimizes L, satisfies Euler's equation of the expression (6) according to the variational method.

$$\frac{\partial g}{\partial y} - \frac{d}{dx} \frac{\partial g}{\partial {y}^{′}} = 0 \qquad Math . 7$$

The expression (7) is obtained by substituting g=n√(1+y′²) into the left side of the expression (6)

$$\begin{matrix}Math . 8 & \\ \sqrt{1 + {( {y}^{′} )}^{2}} \cdot \frac{\partial n}{\partial y} - \frac{d}{dx} \frac{n \cdot {y}^{′}}{\sqrt{1 + {( {y}^{′} )}^{2}}} = 0 & ( 7 )\end{matrix}$$

Modification 1

When the light is incident on the etalon 10 almost in parallel to the x-axis (θ is close to 0), y′<<1 (hence y′²<<1) in the expression (7), so that it can be regarded as √(1+y′²) to 1 and y′/√(1+y′²) to y′, and the expression (7) can be expressed by the expression (8).

$$\begin{matrix}[ Math . 9 ] & \\ \frac{\partial n}{\partial y} - \frac{d}{dx} ( n \cdot {y}^{′} n \cdot {y}^{′} ) = 0 & ( 8 )\end{matrix}$$

### Embodiment 3

By substituting the expression (1) into the expression (8), the following expression (9) is obtained.

Math. 10

2β·(x−x₀)·y′+[1+β·(x−x₀²]·y″=0 (9)

### Embodiment 4

Here, y′=dy/dx, y″=d²y/dx² (=d/dx (dy/dx)). The solution of the differential equation of the expression (9) becomes the expression (10).

Math. 11

y=C₁·\sqrt{β}·tan⁻¹(\sqrt{β}·(x−x₀))+C₂ (10)

Modification 2

Here, C₁ and C₂ are constants, and C₁ and C₂ are obtained as follows.

As shown in FIG. 1, when the incident angle (inside the etalon 10) at the incident position x=0 to the etalon 10 is defined as θᵢ, since y′|ₓ₋₀=tan θᵢ, C₁ is expressed by the expression (11). Here, η′|_{ξ-n}, represents the result of substituting a into ξ in the differential expression for ξ of η. However, the condition of 0<θᵢ<π/2 was imposed on θᵢ, which was transformed to cos θᵢ=√(1−sin² θᵢ).

Modification 3

$$\begin{matrix}Math . 12 & \\ {{y}^{′} {\vert}_{x = 0} = \frac{{C}_{1}}{\frac{1}{β} + {( x - {x}_{0} )}^{2}} \vert}_{x = 0} = \frac{{C}_{1}}{\frac{1}{β} + {x}_{0}^{2}} = tan {θ}_{i} & ( 11 )\end{matrix}$$

$$∴ {C}_{1} = ( \frac{1}{β} + {x}_{0}^{2} ) \cdot tan {θ}_{i}$$

$$Where$$

$$tan {θ}_{i} = \frac{sin {θ}_{i}^{′}}{\sqrt{{{n}_{0}^{2} [ 1 + β \cdot ( x - {x}_{0} ) ]}^{2} - {sin}^{2} {θ}_{i}^{′}}}$$

Furthermore, as shown in FIG. 1, when x=0, y=0 and C₂ is expressed in the expression (12) by the expression (10) and the formula (11).

$$\begin{matrix}Math . 13 & \\ 0 = {C}_{1} \cdot \sqrt{β} \cdot {tan}^{- 1} ( \sqrt{β} \cdot ( 0 - {x}_{0} ) ) + {C}_{2} & ( 12 )\end{matrix}$$

$${C}_{2} = {C}_{1} \cdot \sqrt{β} \cdot {tan}^{- 1} ( \sqrt{β} \cdot {x}_{0} )$$

$$∴ {C}_{1} = ( \frac{1}{\sqrt{β}} + \sqrt{β} \cdot {x}_{0}^{2} ) \cdot tan {θ}_{i} \cdot {tan}^{- 1} ( \sqrt{β} \cdot {x}_{0} )$$

$$Where$$

$$tan {θ}_{i} = \frac{sin {θ}_{i}^{′}}{\sqrt{{{n}_{0}^{2} [ 1 + β \cdot ( x - {x}_{0} ) ]}^{2} - {sin}^{2} {θ}_{i}^{′}}}$$

The optical path y is as shown in the expression (13), from the expression (10), the expression (11), and the expression (12).

$$Math . 14$$

$$\begin{matrix}y & = {C}_{1} \cdot \sqrt{β} \cdot {tan}^{- 1} ( \sqrt{β} \cdot ( x - {x}_{0} ) ) + {C}_{2} \\ & = {C}_{1} \cdot \sqrt{β} \cdot [ {tan}^{- 1} ( \sqrt{β} \cdot ( x - {x}_{0} ) ) + {tan}^{- 1} ( \sqrt{β} \cdot {x}_{0} ) ] \\ & = ( \frac{1}{\sqrt{β}} + \sqrt{β} \cdot {x}_{0}^{2} ) \cdot tan {θ}_{i} \cdot [ {tan}^{- 1} ( \sqrt{β} \cdot ( x - {x}_{0} ) ) + {tan}^{- 1} ( \sqrt{β} \cdot {x}_{0} ) ]\end{matrix} \qquad ( 13 )$$

Here, if the expression (14) is satisfied, then the expression (15) is obtained from the expression (13).

$$Math . 15$$

$$β \cdot {x}_{0} \cdot ( x - {x}_{0} ) < 1 \qquad ( 14 )$$

$$Math . 16$$

$$y = ( \frac{1}{\sqrt{β}} + \sqrt{β} \cdot {x}_{0}^{2} ) \cdot tan {θ}_{i} \cdot {tan}^{- 1} ( \frac{\sqrt{β} \cdot x}{1 - β \cdot {x}_{0} \cdot ( x - {x}_{0} )} ) \qquad ( 15 )$$

The optical path length L of the optical path y is expressed by the expression (16) by substituting the expression (1) and the expression (1) into the expression (5).

$$Math . 17$$

$$\begin{matrix}L & = {\int }_{0}^{d} {n}_{0} \cdot [ 1 + β \cdot {( x - {x}_{0} )}^{2} ] \cdot \sqrt{1 + {( \frac{β \cdot {C}_{1}}{1 + β \cdot {( x - {x}_{0} )}^{2}} )}^{2}} dx \\ & = {n}_{0} \cdot {\int }_{0}^{d} \sqrt{{[ 1 + β \cdot {( x - {x}_{0} )}^{2} ]}^{2} + {( β \cdot {C}_{1} )}^{2} dx}\end{matrix} \qquad ( 16 )$$

The optical path length L of the expression (16) is expressed by a linear sum of a first type elliptic integration EllipticF (Φ, m) and a second type elliptic integration EllipticE (Φ, m).

$$Math . 18$$

$$L = {[ \frac{1}{3 \sqrt{- \frac{j \cdot β}{- j + β \cdot {C}_{1}} \cdot \sqrt{{[ 1 + β \cdot {( x - {x}_{0} )}^{2} ]}^{2} + {( β \cdot {C}_{1} )}^{2}}}} \cdot ( \sqrt{- \frac{j \cdot β}{- j + β \cdot {C}_{1}}} \{ {[ 1 + β \cdot {( x - {x}_{0} )}^{2} ]}^{2} \} ( x - {x}_{0} ) + 2 ( 1 - j \cdot β \cdot {C}_{1} ) \cdot \sqrt{\frac{j [ 1 - j \cdot β \cdot {C}_{1} + β \cdot {( x - {x}_{0} )}^{2} ]}{j + β \cdot {C}_{1}}} \cdot \sqrt{- \frac{j [ 1 + j \cdot β \cdot {C}_{1} + β \cdot {( x - {x}_{0} )}^{2} ]}{- j + β \cdot {C}_{1}}} \cdot [ - j \cdot EllipticE ( j \cdot {sinh}^{- 1} ( \sqrt{- \frac{j \cdot β}{- j + β \cdot {C}_{1}} ( x - {x}_{0} )} ) , - 1 + \frac{j \cdot 2}{j + β \cdot {C}_{1}} ) + β \cdot {C}_{1} \cdot EllipticF ( j \cdot {sinh}^{- 1} ( \sqrt{- \frac{j \cdot β}{- j + β \cdot {C}_{1}} ( x - {x}_{0} )} ) , - 1 + \frac{j \cdot 2}{j + β \cdot {C}_{1}} ) ] ) ]}_{0}^{d} \qquad ( 16 ’ )$$

$$Where$$

$$EllipticF ( ϕ , m ) = {\int }_{0}^{ϕ} \frac{1}{\sqrt{1 - m \cdot {sin}^{2} θ}} d θ$$

$$EllipticE ( ϕ , m ) = {\int }_{0}^{ϕ} \sqrt{1 - m \cdot {sin}^{2} θ} d θ$$

In order to simplify the optical path length L, the optical path length L is approximated by an elementary function. First, the expression (17) is taken as a condition.

Math. 19

1>>(x−x₀)² (17)

In this case, since the optical path length L can be approximated as [1+β(x−x₀)²]² to 1+2β(x−x₀)², the expression (16) can be approximated to the expression (18).

$$Math . 20$$

$$\begin{matrix}L & ≅ {n}_{o} \cdot {\int }_{0}^{d} \sqrt{1 + 2 β \cdot {( x - {x}_{0} )}^{2} + {( β \cdot {C}_{1} )}^{2}} dx \\ & ≅ {n}_{o} {\int }_{0}^{d} \sqrt{2 β \cdot {( x - {x}_{0} )}^{2} + [ 1 + {( β \cdot {C}_{1} )}^{2} ]} dx \\ & ≅ {{n}_{o} [ \frac{1}{2} ( x - {x}_{0} ) \cdot \sqrt{2 β \cdot {( x - {x}_{0} )}^{2} + [ 1 + {( β \cdot {C}_{1} )}^{2} ]} + \frac{1 + {( β \cdot {C}_{1} )}^{2}}{2 \sqrt{2 β}} \cdot ln ( 2 \sqrt{2 β} ( x - {x}_{0} ) + 2 \sqrt{2 β \cdot {( x - {x}_{0} )}^{2} + [ 1 + {( β \cdot {C}_{1} )}^{2} ]} ) ]}_{0}^{d} \\ & ≅ \frac{{n}_{o}}{2} [ ( d - {x}_{0} ) \cdot 2 \sqrt{2 {β ( d - {x}_{0} )}^{2} + [ 1 + {( β \cdot {C}_{1} )}^{2} ]} + {x}_{0} \cdot \sqrt{2 β {x}_{0}^{2} + [ 1 + {( β \cdot {C}_{1} )}^{2} ]} + \frac{1 + {( β \cdot {C}_{1} )}^{2}}{\sqrt{2 β}} \cdot ln ( \frac{\sqrt{2 β \cdot {( d - {x}_{0} )}^{2} + [ 1 + {( β \cdot {C}_{1} )}^{2} ]} + \sqrt{2 β} \cdot ( d - {x}_{0} )}{\sqrt{2 β \cdot {x}_{0}^{2} + [ 1 + {( β \cdot {C}_{1} )}^{2} ]} - \sqrt{2 β} \cdot {x}_{0}} ) ]\end{matrix} \qquad ( 18 )$$

If the refractive index at the center of the etalon 10 in the x-axis direction is the minimum, the expression (19) is obtained, and therefore the optical path length L can be obtained by the expression (20).

$$Math . 21$$

$${x}_{0} = \frac{d}{2} \qquad ( 19 )$$

$$Math . 22$$

$$L {\vert}_{{x}_{0} = \frac{d}{2}} ≅ \frac{{n}_{o}}{2} \cdot [ d \sqrt{\frac{1}{2} β \cdot {d}^{2} + [ 1 + {( β \cdot {C}_{1} )}^{2} ]} + \frac{1 + {( β \cdot {C}_{1} )}^{2}}{\sqrt{2 β}} ln ( \frac{\sqrt{\frac{1}{2} β \cdot {d}^{2} + [ 1 + {( β \cdot {C}_{1} )}^{2} ]} + \sqrt{\frac{1}{2}} \sqrt{β} \cdot d}{\sqrt{\frac{1}{2} β \cdot {d}^{2} + [ 1 + {( β \cdot {C}_{1} )}^{2} ]} - \sqrt{\frac{1}{2}} \sqrt{β} \cdot d} ) ] \qquad ( 20 )$$

The etalon 10 according to the present embodiment is characterized in that the refractive index of a dielectric used in the etalon is changed, thereby suppressing the lateral shift of light that is incident on and emitted from the incident surface of the etalon at a predetermined angle (excluding 0°).

In order to illustrate this, the difference between an emission position of an etalon having a uniform refractive index therein (referred to as “uniform refractive index distribution etalon,” hereinafter) 20 and an emission position of the etalon according to the present embodiment (referred to as “quadratic function refractive index distribution etalon,” hereinafter) is calculated under the condition that the free spectrum intervals (FSR) of the uniform refractive index distribution etalon 20 and the quadratic function refractive index distribution etalon 10 are equal, that is, the optical path lengths are equal.

Here, the lateral shift of the beam is the shift in the y-axis direction in FIG. 1. For example, when the incident position (x, y)=(0, 0) and the emission position (x, y)=(d, y₀), the amount of shift is y₀.

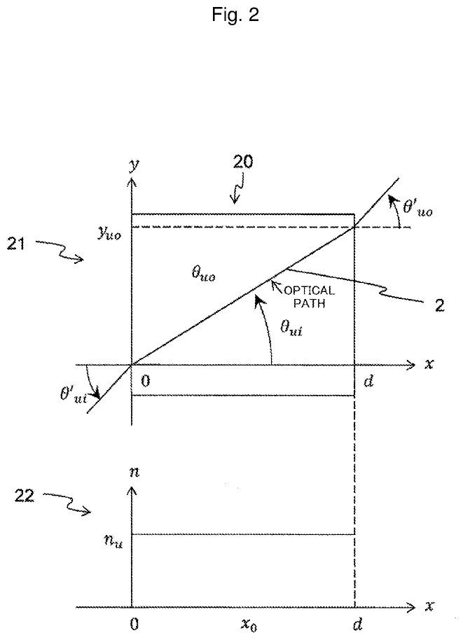

First, the amount of lateral shift of the beam with respect to the uniform refractive index distribution etalon 20 will be described. FIG. 2 shows the optical path 2 and the refractive index distribution 22 in the uniform refractive index distribution etalon 20. The refractive index is constant in the x-axis direction, and the value is nᵤ. Here, the refractive index is also constant in the y-direction (not shown). At this time, the optical path 2 becomes a straight line.

The lateral shift yᵤ₀ of the uniform refractive index distribution etalon 20 shown in FIG. 2 is expressed by the expression (21).

Math. 23

yᵤₒ=d·tan θᵤᵢ (21)

Here, θᵤᵢ is an incident angle within the uniform refractive index distribution etalon 20 at (x, y)=(0, 0). When the incident angle from the outside of the uniform refractive index distribution etalon 20 is taken as θ′ᵤᵢ, the relationship between θᵤᵢ and θ′ᵤᵢ is expressed by the expression (22), from the Snell's law.

$$Math . 24$$

$$\begin{matrix}sin {θ}_{ui} = \frac{1}{{n}_{u}} \cdot sin {θ}_{ui}^{′} & ( 22 )\end{matrix}$$

Therefore, once nᵤ is obtained, the amount of lateral shift yᵤ₀ of the beam by the uniform refractive index distribution etalon 20 can be calculated by determining θ′ᵤᵢ. Next, nᵤ is set (converted) in such a manner that the optical path lengths of the uniform refractive index distribution etalon 20 and the quadratic function refractive index distribution etalon 10 are equal to each other, and the amount of lateral shift yᵤ₀ of the uniform refractive index distribution etalon 20 is calculated.

Since the physical length of the optical path inside the uniform refractive index distribution etalon 20 is d/cos θᵤᵢ, the optical path length Lᵤ is expressed by the expression (23). However, θᵤᵢ is subjected to the condition of 0<θᵤᵢ<π/2 and transformed to cos θᵤᵢ=√(1−sin² θᵤᵢ)

$$Math . 25$$

$${L}_{u} = {n}_{u} \frac{d}{cos {θ}_{ui}} = {n}_{u} \cdot \frac{d}{\sqrt{1 - {sin}^{2} {θ}_{ui}}} \qquad ( 23 )$$

The expression (24) is obtained by substituting the expression (23) into the expression (22).

$$Math . 26$$

$${L}_{u} = {n}_{u} \cdot \frac{d}{\sqrt{1 - \frac{1}{{n}_{u}^{2}} \cdot {sin}^{2} {θ}_{ui}^{′}}} \qquad ( 24 )$$

By squaring both sides of the expression (24), the expression (25) is obtained as a polynomial expression of nᵤ.

$$Math . 27$$

$$\begin{matrix}{n}_{u}^{4} - {( \frac{{L}_{u}}{d} )}^{2} \cdot {n}_{u}^{2} + {( \frac{{L}_{u}}{d} )}^{2} \cdot {sin}^{2} {θ}_{ui}^{′} = 0 & ( 25 )\end{matrix}$$

Since nᵤ>0, when the formula (25) is solved for nᵤ² as a quadratic equation of nᵤ² and nᵤ is obtained, the expression (27) is obtained.

$$Math . 28$$

$${n}_{u} = \sqrt{\frac{1}{2} [ {( \frac{{L}_{u}}{d} )}^{2} \pm \frac{{L}_{u}}{d} \cdot \sqrt{{( \frac{{L}_{u}}{d} )}^{2} - 4 {sin}^{2} {θ}_{ui}^{′}}} ] = \frac{{L}_{u}}{d} \sqrt{\frac{1}{2} [ 1 \pm \sqrt{1 - {( 2 \cdot \frac{d}{{L}_{u}} \cdot sin {θ}_{ui}^{′} )}^{2}} ]} \qquad ( 26 )$$

When “+−” in the expression (26) is “−,” and when the incident angle θ′ᵤᵢ to the uniform refractive index distribution etalon 20 is 0, since the right side of the expression (26) is 0, that is, nᵤ=0 and has no physical meaning, only “+” in the expression (26) is valid. Therefore, nᵤ is expressed by the expression (27).

$$Math . 29$$

$${n}_{u} = \sqrt{\frac{1}{2} [ {( \frac{{L}_{u}}{d} )}^{2} + \frac{{L}_{u}}{d} \cdot \sqrt{{( \frac{{L}_{u}}{d} )}^{2} - 4 {sin}^{2} {θ}_{ui}^{′}}} ] = \frac{{L}_{u}}{d} \sqrt{\frac{1}{2} [ 1 + \sqrt{1 - {( 2 \cdot \frac{d}{{L}_{u}} \cdot sin {θ}_{ui}^{′} )}^{2}} ]} \qquad ( 27 )$$

Since the FSRs of the uniform refractive index distribution etalon 20 and the quadratic function refractive index distribution etalon 10 are the same, that is, the optical path lengths are the same, the Lᵤ=L is satisfied. Here, nᵤ is expressed by the expression (28).

$$Math . 30$$

$$\begin{matrix}{n}_{u} = \sqrt{\frac{1}{2} [ {( \frac{L}{d} )}^{2} + \frac{L}{d} \cdot \sqrt{{( \frac{L}{d} )}^{2} - 4 {sin}^{2} {θ}_{ui}^{′}}} ] = \frac{L}{d} \sqrt{\frac{1}{2} [ 1 + \sqrt{1 - {( 2 \cdot \frac{d}{L} \cdot sin {θ}_{ui}^{′} )}^{2}} ]} & ( 28 )\end{matrix}$$

Here, L is expressed by expression (18). If the expression (19) is established, that is, if the refractive index at the center of the etalon 10 in the x-axis direction is minimum (if x₀=d/2), then L is expressed by the expression (20).

From the expressions (21), (22), and (28), the amount of lateral shift yᵤ₀ of the uniform refractive index distribution etalon 20 is expressed by the formula (29).

$$Math . 31$$

$${y}_{uo} = d \cdot tan {θ}_{ui} = d \cdot \frac{sin {θ}_{ui}}{cos {θ}_{ui}} = d \cdot \frac{\frac{1}{{n}_{u}} \cdot sin {θ}_{ui}^{′}}{\sqrt{1 - \frac{1}{{n}_{u}^{2}} \cdot {sin}^{2} {θ}_{ui}^{′}}} \qquad ( 29 )$$

$$Where$$

$${n}_{u} = \sqrt{\frac{1}{2} [ {( \frac{L}{d} )}^{2} + \frac{L}{d} \cdot \sqrt{{( \frac{L}{d} )}^{2} - 4 {sin}^{2} {θ}_{ui}^{′}}} ] = \frac{L}{d} \sqrt{\frac{1}{2} [ 1 + \sqrt{1 - {( 2 \cdot \frac{d}{L} \cdot sin {θ}_{ui}^{′} )}^{2}} ]}$$

Next, the amount of lateral shift y₀ of the etalon according to the present embodiment, that is, the quadratic function refractive index distribution etalon 10, will be described.

The optical path in the quadratic function refractive index distribution etalon 10 is shown by the expression (13), and by substituting d, which is the thickness of the etalon, into x in the expression (13), the position of the emission position in the y-axis direction, that is, the amount of lateral shift y₀, can be calculated.

Here, the expression (13) uses θᵢ (the incident angle inside the etalon 10 at the incident position (x, y)=(0, 0)). However, since it is difficult to determine (measure) θᵢ, it is difficult to calculate the amount of lateral shift y₀ from the expression (13).

On the other hand, the external incident angle θ′ᵢ of the etalon 10 at the incident position (x, y)=(0, 0) can easily be determined (measured). Therefore, by using θ′ᵢ in place of θᵢ, the amount of lateral shift y₀ can be easily calculated from the expression (13). Therefore, as shown below, the expression (13) is expressed with θ′ᵢ.

By the Snell's law, the relationship between θ′ᵢ and θᵢ is expressed by the expression (30).

$$Math . 32$$

$$sin {θ}_{i} = \frac{1}{n {\vert}_{x = 0}} \cdot sin {θ}_{i}^{′} \qquad ( 30 )$$

However, n|ₓ₋₀ is n when x=0. According to the expression (1), since n=n₀·[1+B (x−x₀)²], n|ₓ₋₀ is expressed by the expression (31).

Math. 33

n|ₓ₌₀=nₒ·(1+β·x₀²) (31)

Accordingly, the expression (30) is expressed in the expression (32).

$$\begin{matrix}Math . 34 & \\ sin {θ}_{i} = \frac{1}{{n}_{o} \cdot ( 1 + β \cdot {x}_{0}^{2} )} \cdot sin {θ}_{i}^{′} & ( 32 )\end{matrix}$$

From the expressions (32) and (33), the optical path of the quadratic function refractive index distribution etalon 10 is expressed by the expression (33). Here, θᵢ is subjected to the condition of 0<θᵢ<π/2 and is transformed to cos θᵢ=√(1−sin²θᵢ).

$$Math . 35$$

$$\begin{matrix}y = ( \frac{1}{\sqrt{β}} + \sqrt{β} \cdot {x}_{0}^{2} ) \cdot tan {θ}_{i} \cdot [ {tan}^{- 1} ( \sqrt{β} \cdot ( x - {x}_{0} ) ) + \\ {tan}^{- 1} ( \sqrt{β} \cdot {x}_{0} ) ] \\ = ( \frac{1}{\sqrt{β}} + \sqrt{β} \cdot {x}_{0}^{2} ) \cdot \frac{sin {θ}_{i}}{\sqrt{1 - {sin}^{2} {θ}_{i}}} \cdot [ {tan}^{- 1} ( \sqrt{β} \cdot ( x - {x}_{0} ) ) + \\ {tan}^{- 1} ( \sqrt{β} \cdot {x}_{0} ) ] \\ = \frac{\frac{1}{\sqrt{β}} \cdot ( 1 + β \cdot {x}_{0}^{2} ) \cdot sin {θ}_{i}^{′}}{\sqrt{{n}_{o}^{2} \cdot {( 1 + β \cdot {x}_{0}^{2} )}^{2} - sin {θ}_{i}^{′}}} \cdot [ {tan}^{- 1} ( \sqrt{β} \cdot ( x - {x}_{0} ) ) + \\ {tan}^{- 1} ( \sqrt{β} \cdot {x}_{0} ) ]\end{matrix} \qquad ( 33 )$$

Here, if the expression (34) is satisfied, the expression (33) is expressed by the expression (35).

$$Math . 36$$

$$β \cdot {x}_{0} \cdot ( x - {x}_{0} ) < 1 \qquad ( 34 )$$

$$Math . 37$$

$$y = \frac{\frac{1}{\sqrt{β}} \cdot ( 1 + β \cdot {x}_{0}^{2} ) \cdot sin {θ}_{i}^{′}}{\sqrt{{n}_{o}^{2} \cdot {( 1 + β \cdot {x}_{0}^{2} )}^{2} - {sin}^{2} {θ}_{i}^{′}}} \cdot tan {θ}_{i} \cdot {tan}^{- 1} ( \frac{\sqrt{β} \cdot x}{1 - β \cdot {x}_{0} \cdot ( x - {x}_{0} )} ) \qquad ( 35 )$$

By substituting d into x of the expression (33), the amount of lateral shift y₀ of the quadratic function refractive index distribution etalon 10 is obtained as the expression (36).

$$\begin{matrix}Math . 38 & \\ {y}_{o} = \frac{\frac{1}{\sqrt{β}} \cdot ( 1 + β \cdot {x}_{0}^{2} ) \cdot sin {θ}_{i}^{′}}{\sqrt{{n}_{o}^{2} \cdot {( 1 + β \cdot {x}_{0}^{2} )}^{2} - {sin}^{2} {θ}_{i}^{′}}} \cdot [ {tan}^{- 1} ( \sqrt{β} \cdot ( d - {x}_{0} ) ) + {tan}^{- 1} ( \sqrt{β} \cdot {x}_{0} ) ] & ( 36 )\end{matrix}$$

Here, if the expression (37) where x of the expression (34) is taken as d is established, the expression (36) is expressed in the expression (38).

$$\begin{matrix}Math . 39 & \\ β \cdot {x}_{0} \cdot ( x - {x}_{0} ) < 1 & ( 37 )\end{matrix}$$

$$\begin{matrix}Math . 40 & \\ {y}_{o} = \frac{\frac{1}{\sqrt{β}} \cdot ( 1 + β \cdot {x}_{0}^{2} ) \cdot sin {θ}_{i}^{′}}{\sqrt{{n}_{o}^{2} \cdot {( 1 + β \cdot {x}_{0}^{2} )}^{2} - {sin}^{2} {θ}_{i}^{′}}} \cdot {tan}^{- 1} ( \frac{\sqrt{β} \cdot x}{1 - β \cdot {x}_{0} \cdot ( d - {x}_{0} )} ) & ( 38 )\end{matrix}$$

In the present embodiment, in order to allow the quadratic function refractive index distribution etalon 10 to exhibit the effects, the amount of lateral shift y₀ of the quadratic function refractive index distribution etalon 10 needs to be smaller than the amount of lateral shift yᵤ₀ of the uniform refractive index distribution etalon 20. Therefore, the expression (39) needs to be satisfied.

Math. 41

yₒ<yᵤₒ (39)

The expression (39) is expressed in the expression (40) from the expression (36) and the expression (29). Here, since the incident angle θ′ᵤᵢ from the outside of the uniform refractive index distribution etalon 20 and the incident angle θ′ᵢ from the outside of the quadratic function refractive index distribution etalon 10 are the same, θ′ᵤᵢ of the expression (29) is replaced with θ′ᵢ.

$$\begin{matrix}Math . 42 & \\ {tan}^{- 1} ( \sqrt{β} \cdot ( d - {x}_{0} ) ) + {tan}^{- 1} ( \sqrt{β} \cdot {x}_{0} ) < \frac{\sqrt{β} \cdot d}{1 + β \cdot {x}_{0}^{2}} \sqrt{\frac{{n}_{o}^{2} \cdot {( 1 + β \cdot {x}_{0}^{2} )}^{2} {sin}^{2} {θ}_{i}^{′}}{{n}_{u}^{2} - {sin}^{2} {θ}_{i}^{′}}} & ( 40 )\end{matrix}$$

$$Where$$

$${n}_{u} = \sqrt{\frac{1}{2} [ {( \frac{L}{d} )}^{2} + \frac{L}{d} \cdot \sqrt{{( \frac{L}{d} )}^{2} - 4 {sin}^{2} {θ}_{i}^{′}} ]} = \frac{L}{d} \sqrt{{\frac{1}{2} [ 1 + \sqrt{1 - ( 2 \cdot \frac{d}{L} \cdot sin {θ}_{i}^{′}} )}^{2} ]}$$

Here, if the expression (37) is satisfied, the condition expression (39) is expressed in the expression (41) from the expression (38) and the expression (29).

$$\begin{matrix}Math . 43 & \\ {tan}^{- 1} ( \frac{\sqrt{β} \cdot d}{1 - β \cdot {x}_{0} \cdot ( d - {x}_{0} )} ) < \frac{\sqrt{β} \cdot d}{1 + β \cdot {x}_{0}^{2}} \sqrt{\frac{{n}_{o}^{2} \cdot {( 1 + β \cdot {x}_{0}^{2} )}^{2} - {sin}^{2} {θ}_{i}^{′}}{{n}_{u}^{2} - {sin}^{2} {θ}_{i}^{′}}} & ( 41 )\end{matrix}$$

$$Or , \frac{\sqrt{β} \cdot d}{1 - β \cdot {x}_{0} \cdot ( d - {x}_{0} )} < tan ( \frac{d \cdot \sqrt{β}}{1 + β \cdot {x}_{0}^{2}} \sqrt{\frac{{n}_{o}^{2} \cdot {( 1 + β \cdot {x}_{0}^{2} )}^{2} - {sin}^{2} {θ}_{i}^{′}}{{n}_{u}^{2} - {sin}^{2} {θ}_{i}^{′}}} )$$

$$Where$$

$${n}_{u} = \sqrt{\frac{1}{2} [ \frac{L}{d} + \frac{L}{d} \cdot \sqrt{{( \frac{L}{d} )}^{2} - 4 {sin}^{2} {θ}_{i}^{′} ]}} = \frac{L}{d} \sqrt{\frac{1}{2} [ 1 + \sqrt{1 - {( 2 \cdot \frac{d}{L} \cdot sin {θ}_{i}^{′} )}^{2} ]}}$$

As described above, in satisfying the expression (40) or the expression (41), the quadratic function refractive index distribution etalon 10 according to the present embodiment has a smaller amount of lateral shift of light incident on and emitted from the incident surface of the etalon at a predetermined angle (excluding 0°) than the uniform refractive index distribution etalon 20.

That is, in satisfying the expression (40) or the expression (41), the quadratic function refractive index distribution etalon 10 according to the present embodiment can suppress the lateral shift of the light.

In this manner, the refractive index distribution of the etalon 10 according to the present embodiment is set so that the lateral shift thereof is smaller than that of the uniform refractive index distribution etalon under the condition that the optical path lengths of light transmitted through the etalon are equal.

When comparing the lateral shifts, the lateral shift of the etalon 10 and the lateral shift of the uniform refractive index distribution etalon are expressed by the incident angle of light transmitted through the etalon from the outside.

### Effects of Etalon

As an example of the effects of the quadratic refractive index distribution etalon 10 according to the present embodiment, now are described the calculation results of the beam lateral shift obtained when the incident angle θ′ᵢ from the outside of etalon 10 is changed in a case where the position x₀ where the refractive index is minimum is the center of the etalon 10 in the x-axis direction, that is, in a case where x₀=d/2 when the thickness of the etalon 10 is d and the etalon 10 is from 0 to d in the x-axis.

The parameters used in the calculations are as follows
Refractive index distribution constant β: 120000 m⁻²
Etalon thickness d: 1 mm (0.001 m)
Minimum refractive index position x₀: 0.5 mm (0.0005 m)
Incident angle θ′ᵢ from outside of etalon: 0 to 10°
Minimum refractive index n₀: 1.5

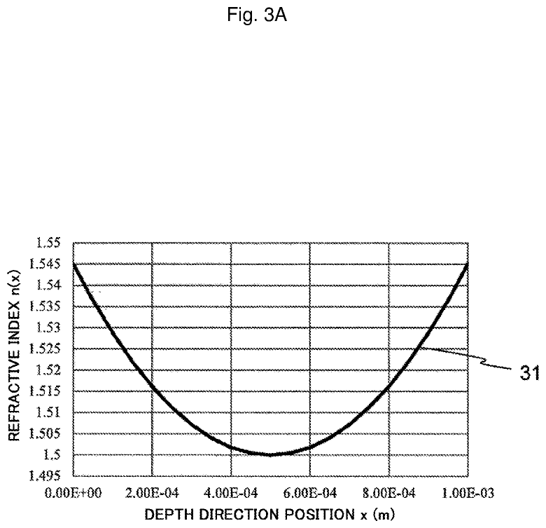

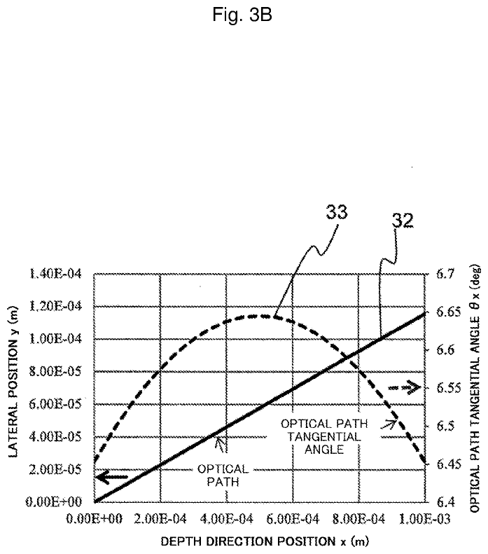

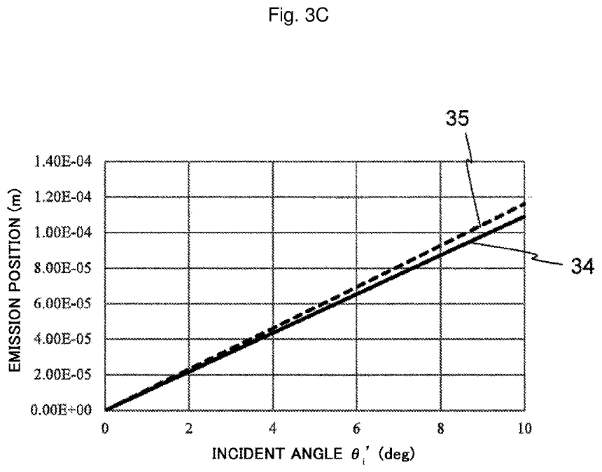

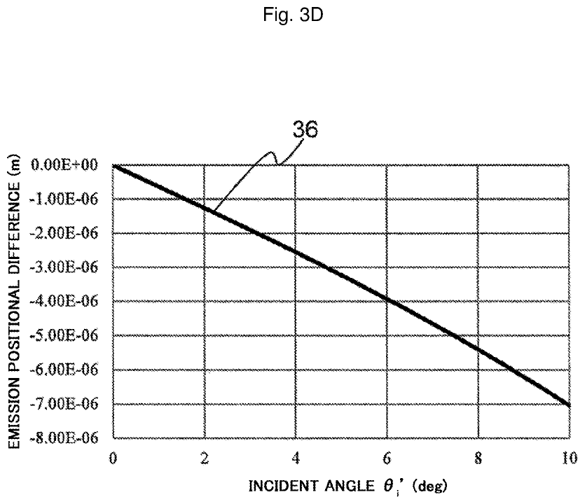

s shown in FIG. 3A, the refractive index distribution 31 in the x-axis direction is a refractive index distribution according to a downwardly convex quadratic function with x₀=0.5 mm and a minimum refractive index of 1.5. The refractive index distribution in the y-axis direction is constant.

FIG. 3B shows an optical path (solid line) 32 in the quadratic function refractive index distribution etalon 10 and an angle (broken line) 33 formed by a tangent line to the optical path 32 and the x-axis. The incident angle θ′ᵢ from the outside of the etalon 10 was calculated as 10°. Although the optical path 32 is substantially a straight line, the angle 33 of the tangent line of the optical path is not constant but is changed, and therefore it is understood that the optical path 32 is a curve.

FIG. 3C shows a plot 34 obtained by plotting the position y₀ at which light incident on (x, y)=(0, 0) at an incident angle of 10° is emitted at the quadratic function refractive index distribution etalon 10, with respect to the incident angle θ′ᵢ from the outside of the etalon. For comparison, a plot 35 of the emission position yᵤ₀ of the uniform refractive index distribution etalon 20 is also shown. Since the light is made incident on (x, y)=(0, 0), the emission position in the y-axis direction (the value of the vertical axis in FIG. 3C) becomes the amount of lateral shift by the etalon.

FIG. 3D shows a plot 36 of a difference in the amount of lateral shift, y₀−yᵤ₀, between the emission position y₀ of the quadratic function refractive index distribution etalon 10 in FIG. 3C and the emission position yᵤ₀ of the uniform refractive index distribution etalon 20. In any of the cases where θ′ᵢ is 0 to 10°, y₀−yᵤ₀ results in a negative amount, and y₀<yᵤ₀ is established, that is, the amount of lateral shift is smaller in the quadratic function refractive index distribution etalon 10.

The optical path tangential angle described in the graph of FIG. 3B is calculated by the expression (42).

$$\begin{matrix}Math . 44 & \\ θ ( x ) = {tan}^{- 1} ( \frac{d y}{d x} ) = {tan}^{- 1} ( \frac{{C}_{1}}{\frac{1}{β} + {( x - {x}_{0} )}^{2}} ) & ( 42 )\end{matrix}$$

$$Where {C}_{1} = ( \frac{1}{β} + {x}_{0}^{2} ) \cdot tan {θ}_{i}$$

$$tan {θ}_{i} = \frac{sin {θ}_{i}}{\sqrt{{{n}_{o}^{2} [ 1 + β \cdot ( x - {x}_{0} ) ]}^{2} - {sin}^{2} {θ}_{i}^{′}}}$$

As an example hereinafter, now are described the calculation results of the beam shift obtained when the refractive index minimum position x₀ is changed, with the incident angle θ′ᵢ from the outside of the etalon 10 being constant.

The parameters used in the calculations are as follows
Refractive index distribution constant β: 120000 m⁻²
Etalon thickness d: 1 mm (0.001 m)
Minimum refractive index position x₀: 0 to 0.5 mm (0 to 0.0005 m)
Incident angle θ′ᵢ from outside of etalon: 10°
Minimum refractive index n₀: 1.5

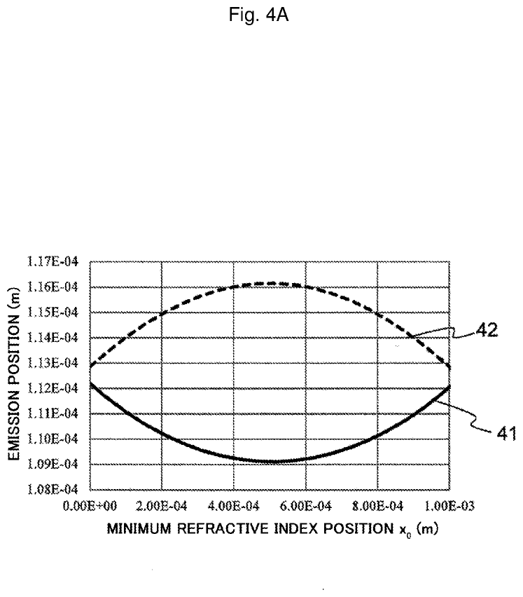

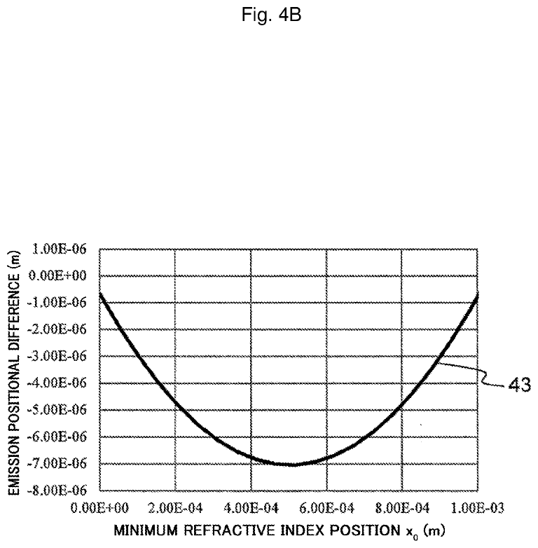

FIG. 4A shows a plot 41 obtained by plotting the position y₀ at which light incident on (x, y)=(0, 0) at an incident angle of 10° is emitted at the quadratic function refractive index distribution etalon 10, with respect to the minimum refractive index position x₀. Since the light is made incident on (x, y)=(0, 0), the emission position in the y-axis direction (the value of the vertical axis in FIG. 4A) becomes the amount of lateral shift of the etalon.

For comparison, a plot 42 of the emission position yᵤ₀ of the uniform refractive index distribution etalon 20 is also shown. Here, the emission position yᵤ₀ is calculated by converting the refractive index in such a manner that the optical path in the uniform refractive index distribution etalon 20 becomes equal to the optical path in the quadratic function refractive index distribution etalon 10. In this calculation process, the position at which the refractive index becomes minimum is plotted as x₀.

FIG. 4B shows a plot 43 of a difference in the amount of lateral shift, y₀−yᵤ₀, between the emission position y₀ of the quadratic function refractive index distribution etalon 10 in FIG. 4A and the emission position yᵤ₀ of the uniform refractive index distribution etalon 20. In any of the cases where x₀ is 0 to 1 mm, y₀−yᵤ₀ results in a negative amount, and y₀<yᵤ₀ is established, that is, the amount of lateral shift is smaller in the quadratic function refractive index distribution etalon 10.

The above calculation results indicate that the lateral shift of light transmitting the etalon can be suppressed at a predetermined incident angle range (0 to 10°) or an arbitrary refractive index minimum position x₀ by setting the refractive index distribution constant β and the etalon thickness d so as to satisfy the expression (40) or the expression (41) in the quadratic function refractive index distribution etalon 10.

### Second Embodiment

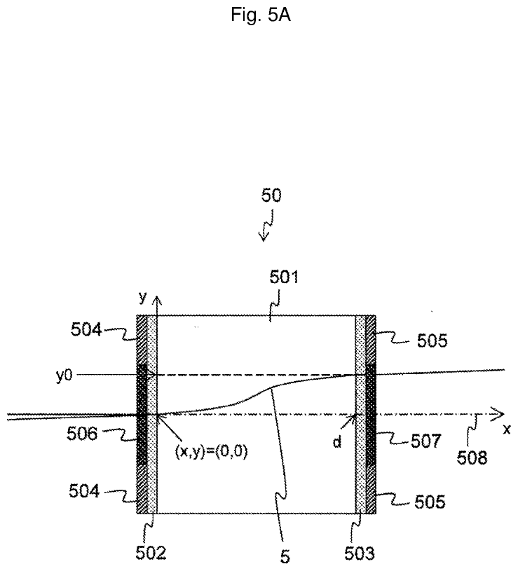

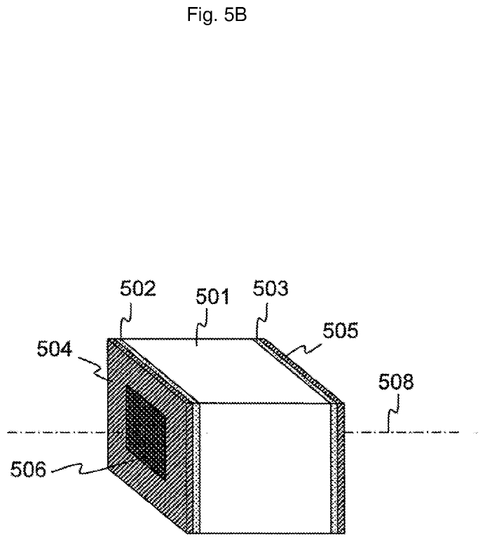

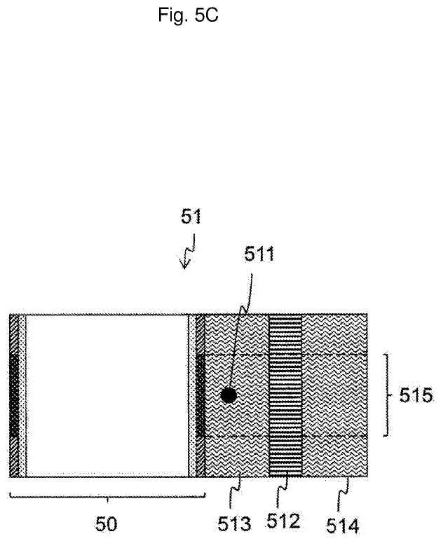

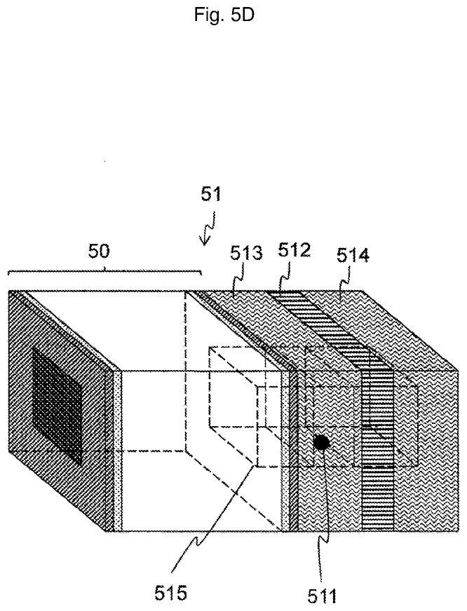

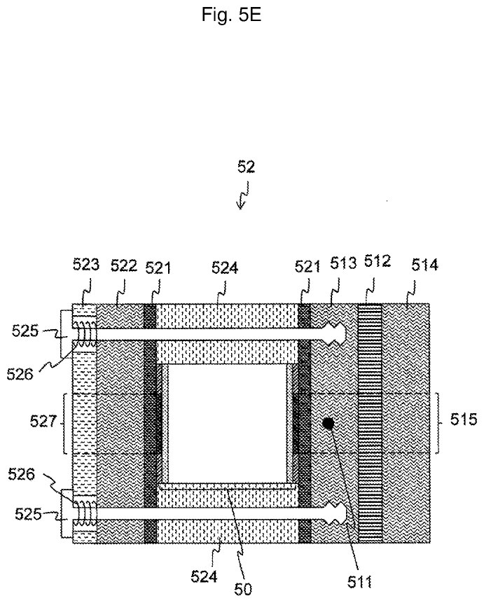

Next, an etalon according to a second embodiment of the present invention will be described with reference to FIGS. 5A and 5B.

### Configuration of Etalon

Now is described an example of using potassium tantalate niobate (KTN, KTaₓNb₁₋ₓO₃) crystal, a material with electro-optic effects, as a medium material that transmits etalon light (with a quadratic function refractive index distribution).

The KTN crystal has a second-order electro-optic effect (the refractive index changes in proportion to the square of the electric field), and allows charges (electrons) to be injected or trapped inside the KTN crystal. By using this feature, a refractive index distribution represented by a quadratic function shown in FIG. 1 is realized as will be described later.

FIG. 5A and FIG. 5B show an example of the structure of an etalon (hereinafter referred to as a “KTN crystal quadratic function refractive index distribution etalon”) 50 having a quadratic function refractive index distribution using the KTN crystal. FIG. 5A is a side view of the etalon 50, and FIG. 5B is a perspective view of the etalon 50.

A pair of opposing two surfaces of a KTN crystal 501 of a rectangular parallelepiped are mirror-polished, transparent electrodes 502 and 503 are formed on the respective two surfaces, and electrodes 504 and 505 and semi-reflecting mirrors 506 and 507 are formed on the transparent electrodes 502 and 503 so as not to overlap each other.

When charges to be injected from the electrodes to the KTN crystal 501 are electrons, it is desirable that the work function be 5.0 eV or less in order for the transparent electrodes 502 and 503 to form an ohmic contact with the KTN crystal 501 (see PTL 1). As an example of the transparent electrodes satisfying this, there exists In₂O₃:Sn(ITO), the work function of which is 4.5 to 4.7 eV (see Japanese Patent Application No. 6440169).

As the semi-reflecting mirrors 506 and 507, a dielectric multilayer film is preferably used, realizing a reflectance of 98% to 99%. Example of the electrodes include electrodes obtained by laminating titanium Ti, platinum Pt, and gold Au on the transparent electrodes 502 and 503 in this order.

As shown in FIG. 5A, an xy coordinate origin is present on the boundary surface between the transparent electrode 502 and the KTN crystal 501, an axis passing through this origin and perpendicular to the boundary surface between the transparent electrode 502 and the KTN crystal 501 is defined as an x-axis 508, and an axis perpendicular to the x-axis, parallel to the side surface and passing through the origin is defined as a y-axis.

Light incident on the etalon 50 from the left side in FIG. 5A and passing through the xy coordinate origin through the semi-reflecting mirror 506 and the transparent electrode 502 advances according to the quadratic function refractive index distribution in the KTN crystal 501, and the light is then emitted from (x, y)=(d, y₀) on the right side surface of the KTN crystal 501 in FIG. 5A, passes through the transparent electrode 503 and the semi-reflecting mirror 507, and is emitted to the outside of the etalon 50.

At this time, y₀ is the amount of shift of the beam. However, it is assumed that the optical path 5 of the incident light to the etalon 50 is on the xy plane.

Although the crystal structure of the KTN crystal 501 changes with temperature, in the present embodiment, the KTN crystal 501 is used as a cubic crystal of a paraelectric phase by keeping a constant temperature at a temperature higher than the Curie temperature by a few degrees (2 to 3° C.). Therefore, the temperature of the KTN crystal 501 needs to be controlled.

In the KTN crystal quadratic function refractive index distribution etalon 50 according to the present embodiment, charges are injected from the electrodes to the KTN crystal 501 in order to change the refractive index of the KTN crystal 501 by a quadratic function. In order to inject the charges, a direct-current (DC) voltage or an alternating-current (AC) voltage of approximately 20 kHz or less is applied from the outside.

### Third Embodiment

An etalon according to a third embodiment of the present invention will be described next with reference to FIGS. 5C and 5D.

In the second embodiment, in order to inject charges from the electrodes to the KTN crystal 501, a direct-current (DC) voltage or an alternating-current (AC) voltage of approximately 20 kHz or less is applied from the outside. In the present embodiment, in order to change the minimum refractive index position x₀, a voltage of a frequency higher than approximately 20 kHz is applied in addition to the DC voltage or AC voltage (approximately 20 kHz or less) described above.

When an AC voltage of approximately 20 kHz or less is applied to the etalon, the etalon generates heat by vibration of the etalon or vibration of a carrier inside the etalon. Therefore, a configuration for controlling the temperature of the etalon is required.

### Configuration of Etalon

As shown in FIGS. 5C and 5D, an etalon 51 according to the present embodiment has a configuration for temperature control including the KTN crystal quadratic function refractive index distribution etalon 50, a thermistor 511 as a temperature sensor, and a Peltier element 512.

A metal block 513, the Peltier element 512, and a heat sink (a metal block, a metal block with a fin, etc.) 514 are arranged on one side of the light incident/emission surface of the etalon 50, and the space between the etalon 50 and the metal block 513, the space between the metal block 513 and the Peltier element 512, and the space between the Peltier element 512 and the heat sink 514 are bonded by an adhesive having high thermal conductivity.

The thermistor (sensor) 511 for measuring temperatures is fixed in a hole of the metal block 513. The thermistor (sensor) 511 may be fixed to a surface of the metal block 513.

Holes 515 for allowing the passage of light are formed in the metal block 513, the Peltier element 512, and the heat sink 514, as shown by broken lines in FIGS. 5C and 5D.

The voltage may be applied to the etalon 50 by bonding lead wires to the two electrodes 504 and 505 of the etalon 50, or the voltage may be applied to one side of the lead wires via the metal block 513 with which the electrodes 504 and 505 are in contact. As a material of the metal block 513, aluminum, copper, copper tungsten or the like can be considered.

### Fourth Embodiment

Next, an etalon according to a fourth embodiment of the present invention will be described with reference to FIG. 5E.

### Configuration of Etalon

As shown in FIG. 5E, an etalon 52 according to the present embodiment has a configuration for controlling temperatures. The etalon 50 is sandwiched between the metal blocks 513 and 522 via a conductive buffer sheet 521. The conductive buffer sheet 521 is composed of a material that has good thermal conductivity, is conductive, and is soft and returns to its original shape when pressed, such as a cushion.

Furthermore, the etalon 51 includes a cap 523, a spacer 524, a bolt 525, and a spring 526, in order to bring the etalon 50 and two conductive buffer sheets 521 into close contact with each other.

In the etalon 51, a screw hole is formed in the metal block 513, and the bolt 525 is inserted through a hole formed in the metal block 522. The bolt 525 is fastened to fix the etalon 50 by being sandwiched between the metal blocks 513 and 522 and the conductive interference sheets 521.

The spring 526 is inserted, locked or attached into the bolt 525, and adjusted in such a manner that a suitable pressure of approximately a few N (1 to 2 N) is applied to the conductive buffer sheets 521 and the metal blocks 513 and 522.

The cap 523 is disposed between the metal block 513 and the head of the bolt 525 to protect the spring 526. The thickness of the cap 523 serves as an index of the length of the spring 526 required to obtain an appropriate repulsive force when the bolt 525 is tightened.

The spacer 524 is disposed so as to sandwich the etalon 50 in order to fix the etalon 50 in the y-direction, and is fixed by the bolt 525.

The size of the spacer in the lateral direction (x direction, etalon thickness direction) is slightly smaller than the size of the etalon 50 in the lateral direction of the etalon 50 (x direction) (by approximately 10 μm to 50 μm). This is to prevent the conductive buffer sheets 521 from shrinking when pressed against the etalon 50.

On one semi-reflecting mirror 507 side of the etalon 50, the holes 515 (broken lines in FIG. 5E) for allowing the passage of light are formed in the conductive buffer sheets 521, the metal block 513, the Peltier element 512, and the heat sink 514. Similarly, on the other semi-reflecting mirror 506 side of the etalon 50, holes 527 (broken lines in FIG. 5E) for allowing the passage of light are formed in the conductive buffer sheets 521, the metal block 513, and the cap 523.

The metal block 513, the Peltier element 512, and the heat sink 514 are bonded to each other by an adhesive having a good thermal conductivity. Other members are not bonded.

The voltage may be applied to the etalon 50 by bonding (fixing) lead wires to the two electrodes 504 and 505 of the etalon 50. Alternatively, the voltage may be applied through the metal blocks 513 and 522.

The material of the conductive buffer sheets 521 is graphite, carbon, conductive rubber, indium, or the like. The material of the bolt 525 is plastic or the like. The material of the metal block 513 is aluminum, copper, copper tungsten, or the like.

### Operation of Etalon (Action)

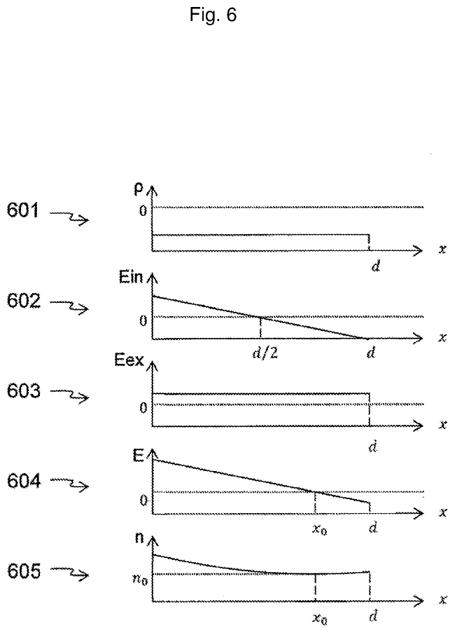

FIG. 6 shows an example of a refractive index distribution obtained when charges (electrons) are injected into the KTN crystal and an electric field is applied from the outside of the KTN crystal. The x-axis in the diagram is the same as the x-axis of FIG. 5A.

In the case where the density of the charges (electrons) is uniformly distributed with respect to x (601 in FIG. 6), an electric field (602 in FIG. 6) expressed by the expression (43) is generated from the charge distribution and the Gaussian law. However, within the KTN crystal in FIG. 5A and in a plane parallel to the plane of the transparent electrodes 502 and 503 (the plane containing the y-axis and the axis perpendicular to the xy-plane and the plane parallel to that plane), the electric field is constant.

$$\begin{matrix}Math . 45 & \\ {E}_{i n} ( x ) = \frac{ρ}{{ε}_{r} {ε}_{0}} ( x - \frac{d}{2} ) & ( 43 )\end{matrix}$$

Here, ρ is a charge density, εᵣ is a relative dielectric constant of the KTN crystal, ε₀ is a dielectric constant of a vacuum (also referred to as electric constant), and d is the thickness of the KTN crystal (the distance between the transparent electrodes).

When a voltage (KTN crystal applied voltage) V is applied between the electrodes of the KTN crystal, an electric field (603 in FIG. 6) expressed by the expression (44) is generated inside the KTN crystal.

$$\begin{matrix}Math . 46 & \\ {E}_{ex} ( x ) = \frac{V}{d} & ( 44 )\end{matrix}$$

An electric field E (604 in FIG. 6) which is generated inside the KTN crystal is expressed by the expression (45) by adding Eᵢₙ(x) and Eₑₓ(x).

$$\begin{matrix}Math . 47 & \\ E ( x ) = {E}_{i n} ( x ) + {E}_{e x} ( x ) = \frac{ρ}{{ε}_{r} {ε}_{0}} [ x - ( \frac{d}{2} - \frac{{ε}_{r} {ε}_{0} V}{ρ d} ) ] & ( 45 )\end{matrix}$$

Since the KTN crystal has the Kerr effect, the refractive index change Δn is proportional to the square of the electric field, as shown in Δn(x) in the expression (46) (Jun Miyazu, Tadayuki Imai, Seiji Toyoda, Masahiro Sasaura, Shogo Yagi, Kazutoshi Kato, Yuzo Sasaki, and Kazuo Fujiura, “New Beam Scanning Model for High-Speed Operation Using KTa1-xNbxO3 Crystals,” Applied Physics Express, Vol. 4, pp. 111501-1-111501-3, 2011.)

$$\begin{matrix}Math . 48 & \\ \begin{matrix}Δ n ( x ) = - \frac{1}{2} {n}_{0}^{3} {{g}_{12} ( {ε}_{r} {ε}_{0} E ( x ) )}^{2} \\ = - \frac{1}{2} {n}_{0}^{3} {{g}_{12} [ ( {ε}_{r} {ε}_{0} {E}_{i n} ( x ) + {E}_{e x} ( x ) ) ]}^{2} \\ = - \frac{1}{2} {n}_{0}^{3} {g}_{12} {{ρ}^{2} [ x - ( \frac{d}{2} - \frac{{ε}_{r} {ε}_{0} V}{ρ d} ) ]}^{2}\end{matrix} & ( 46 )\end{matrix}$$

Here, n₀ is a refractive index when an electric field is not applied (V=0). Also, g₁₂ is an electro-optical constant, and is an amount affecting the direction of the electric field of light in the direction perpendicular to the direction of the electric field applied to the crystal.

As shown in FIG. 5A, the direction of the electric field E(x) is substantially perpendicular to the x-axis direction because the light travels substantially in the x-axis direction, but Δn is proportional to g₁₂ (E(x))² because the electric field in the x-axis direction is generated in the KTN crystal.

Since the electric field of the light is perpendicular to the traveling direction of the light, in the configuration shown in FIG. 5A, the refractive index distribution is independent of polarization of the light (does not depend on the polarization).

The value obtained by adding no to the Δn is the refractive index distribution n(x) of the KTN crystal, and is expressed by the expression (47).

$$\begin{matrix}Math . 49 & \\ \begin{matrix}n ( x ) = {n}_{0} + Δ n ( x ) = {n}_{0} - \frac{1}{2} {n}_{0}^{3} {{g}_{12} ( {ε}_{r} {ε}_{0} E ( x ) )}^{2} \\ = {n}_{0} - \frac{1}{2} {n}_{0}^{3} {g}_{12} {{ρ}^{2} [ x - ( \frac{d}{2} - \frac{{ε}_{r} {ε}_{0} V}{ρ d} ) ]}^{2} \\ = {n}_{0} \{ 1 - \frac{1}{2} {n}_{0}^{3} {g}_{12} {{ρ}^{2} [ x - ( \frac{d}{2} - \frac{{ε}_{r} {ε}_{0} V}{ρ d} ) ]}^{2} \}\end{matrix} & ( 47 )\end{matrix}$$

Thus, when the KTN crystal is used in FIG. 5A, the etalon has a refractive index distribution which becomes a quadratic function of x with respect to the x-axis. Compared with the expression (1), the expression (48) is obtained.

$$\begin{matrix}Math . 50 & \\ β = - \frac{1}{2} {n}_{0}^{2} {g}_{12} {ρ}^{2} & ( 48 )\end{matrix}$$

$${x}_{0} = \frac{d}{2} - \frac{{ε}_{r} {ε}_{0} V}{ρ d}$$

Effects of Etalon

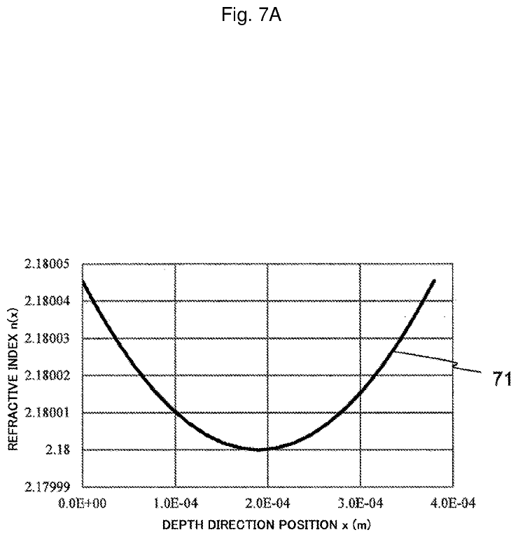

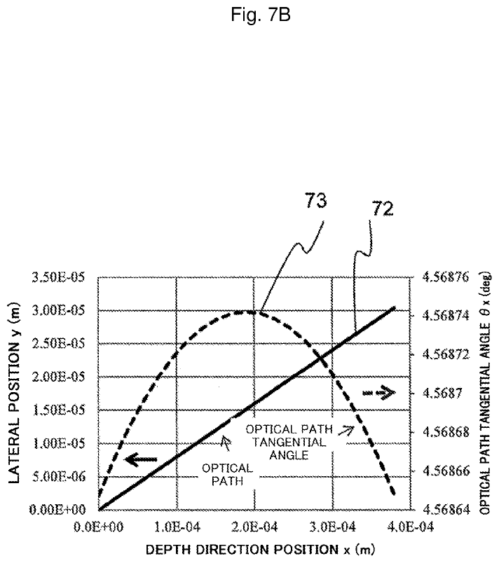

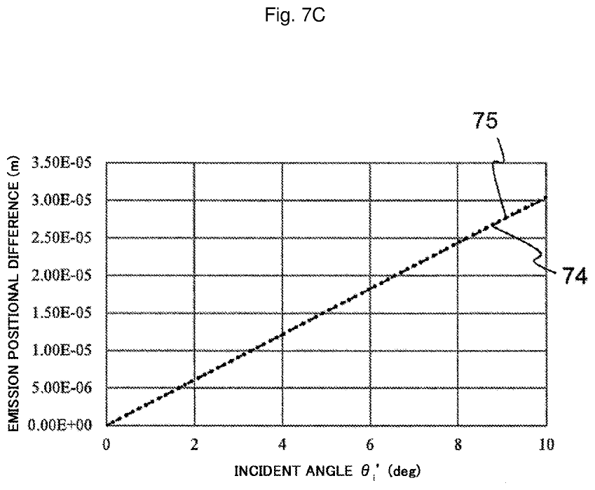

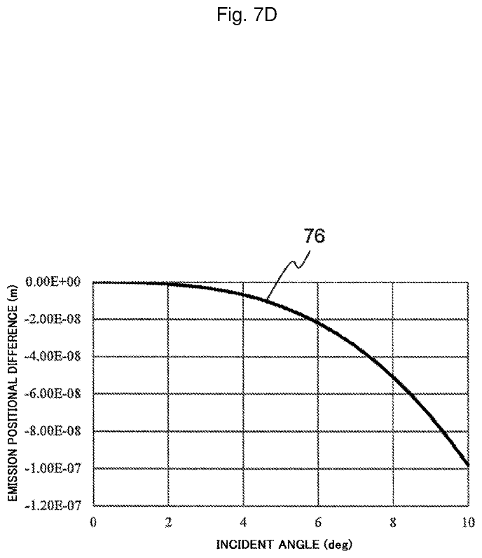

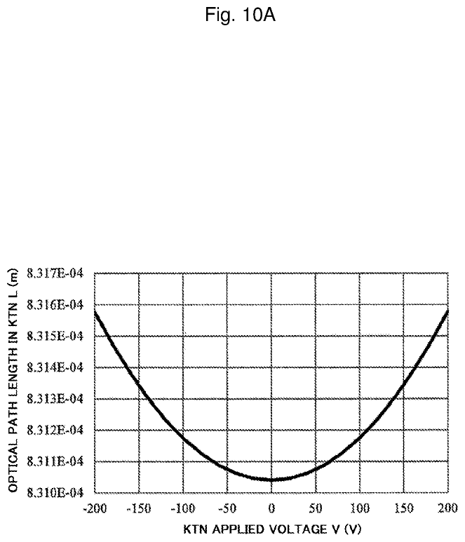

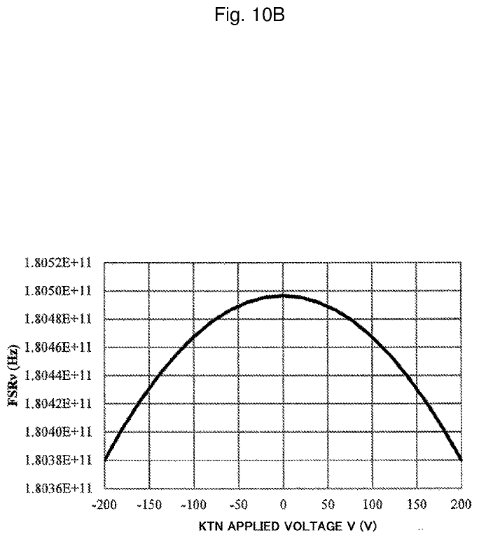

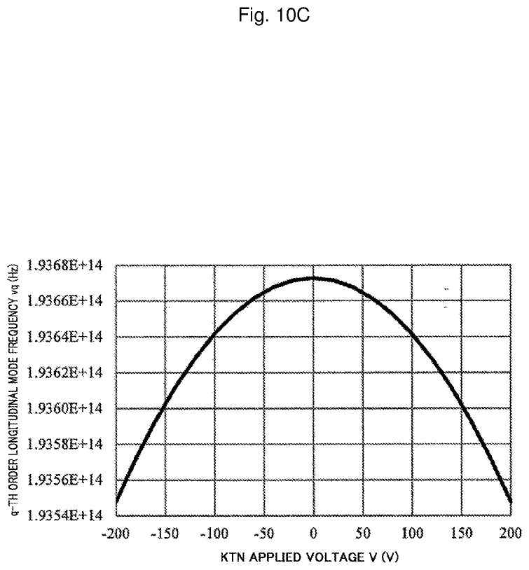

Next, the lateral shift of the beam in the KTN crystal quadratic function refractive index distribution etalon 50 according to the second to fourth embodiments will be described with reference to FIG. 7A and FIG. 10C.

In the KTN crystal quadratic function refractive index distribution etalon 50, an incident angle θ′ᵢ from the outside of the etalon was changed, with the applied voltage V between the electrodes of the KTN crystal being set at 0, and the refractive index distribution in the KTN crystal, the refractive index distribution inside the KTN crystal, the optical path inside the KTN crystal, and the beam emission position were calculated.

For comparison, the same calculation was performed for the uniform refractive index distribution etalon. Here, the uniform refractive index distribution etalon has the same FSR as the KTN crystal quadratic function refractive index distribution etalon 50, that is, the optical path length inside the etalon is equal to that of the KTN crystal quadratic function refractive index distribution etalon 50.
Charge density ρ: −80 cm⁻³
Relative dielectric constant of KTN crystal εᵣ: 17500
Dielectric constant of vacuum (electric constant) ε₀: 8.8541878129×10−12 Fm−1
Thickness of KTN crystal (distance between transparent electrodes) d: 0.38 mm (0.00038 m)
Refractive index of KTN crystal when electric field is not applied (V=0) n₀: 2.18
Electro-optical constant g₁₂: −0.038 C⁴m⁻²
Voltage between electrodes of KTN crystal V: 0 V
Incident angle θ′ᵢ from outside etalon: 0 to 10°

At this time, β=577.8918 m⁻², x₀=1.9×10−4−5.0969831×10⁻⁶×V=1.9×10⁻⁴ m.

In a refractive index distribution 71 shown in FIG. 7A, since V=0, x₀=d/2=1.9×10⁻⁴ mm. Therefore, from the expression (45), a downwardly convex quadratic function is obtained in which the center of the KTN crystal in the x-axis direction has the minimum refractive index n₀=2.18. The refractive index distribution in the y-axis direction is constant.

FIG. 7B shows an optical path (solid line) 72 in the KTN crystal quadratic function refractive index distribution etalon 50 and an angle (broken line) 73 formed by a tangent line to the optical path 72 and the x-axis. The incident angle θ′ᵢ from the outside of the etalon 50 was calculated as 10°. Although the optical path 72 is substantially a straight line, the angle 73 of the tangent line of the optical path is not constant but is changed, and therefore it is understood that the optical path 72 is a curve.

FIG. 7C shows a plot 74 obtained by plotting the position y₀ at which light incident on (x, y)=(0, 0) at an incident angle of 10° is emitted at the KTN crystal quadratic function refractive index distribution etalon 50, with respect to the incident angle θ′ᵢ from the outside of the etalon. Since the light is made incident on (x, y)=(0, 0), the emission position in the y-axis direction (the value of the vertical axis in FIG. 7C) becomes the amount of lateral shift by the etalon. For comparison, a plot 75 of the emission position yᵤ₀ of the uniform refractive index distribution etalon is also shown.

FIG. 7D shows a plot 76 of a difference in the amount of lateral shift, y₀−yᵤ₀, between the emission position y₀ of the KTN crystal quadratic function refractive index distribution etalon 50 in FIG. 7C and the emission position yᵤ₀ of the uniform refractive index distribution etalon. In any of the cases where θ′ᵢ is 0 to 10°, y₀−yᵤ₀ results in a negative amount, and y₀<yᵤ₀ is established, that is, the amount of lateral shift is smaller in the KTN crystal quadratic function refractive index distribution etalon 50.

The optical path tangential angle described in the graph of FIG. 7B is calculated by the expression (42).

Next is described a calculation result of the lateral shift of the beam obtained when the incident angle θ′ᵢ from the outside of the etalon is made constant, and the voltage between the electrodes of the KTN crystal (applied voltage) V is changed to vary the minimum refractive index position x₀. The following parameters were used for the calculation.
Charge density ρ: −80 cm⁻³
Relative dielectric constant of KTN crystal εᵣ: 17500
Dielectric constant of vacuum (electric constant) ε₀: 8.8541878129×10−12 Fm−1
Thickness of KTN crystal (distance between transparent electrodes) d: 0.38 mm (0.00038 m)
Refractive index of KTN crystal when electric field is not applied (V=0) n0: 2.18
Electro-optical constant g₁₂: −0.038 C⁴m⁻²
Voltage between electrodes of KTN crystal (alternating-current) V: −200 to +200
Incident angle θ′ᵢ from outside of etalon: 10°

At this time, β=577.8918 m⁻², x₀=1.9×10−4−5.0969831×10⁻⁶×V=−8.29396623×10⁻⁴ to 1.20939662×10⁻³ m.

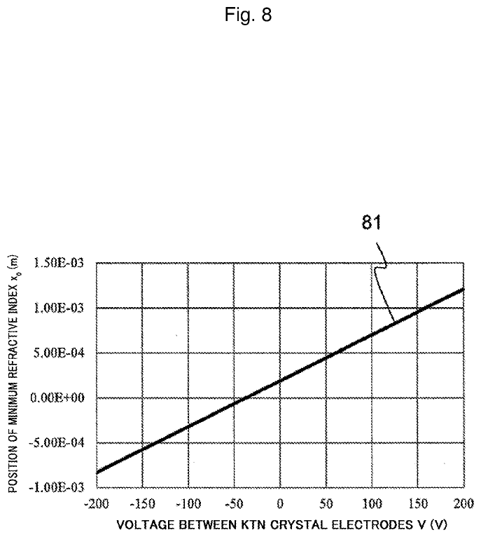

FIG. 8 shows the position x₀ of the minimum refractive index, which is obtained from the expression (48), accompanying a change in the voltage between the electrodes of the KTN crystal (KTN crystal applied voltage) V. x₀ shifts linearly with respect to V. Here, the positive inclination in the graph of FIG. 8 is ρ<0.

Here, the length of the KTN crystal 501 in the x-axis direction corresponds to the range of 0 to 0.38 mm on the vertical axis of FIG. 8. Further, by the V, the position of x₀ can be set outside the range of the KTN crystal (longer than 0.38 mm in the vertical axis of FIG. 8).

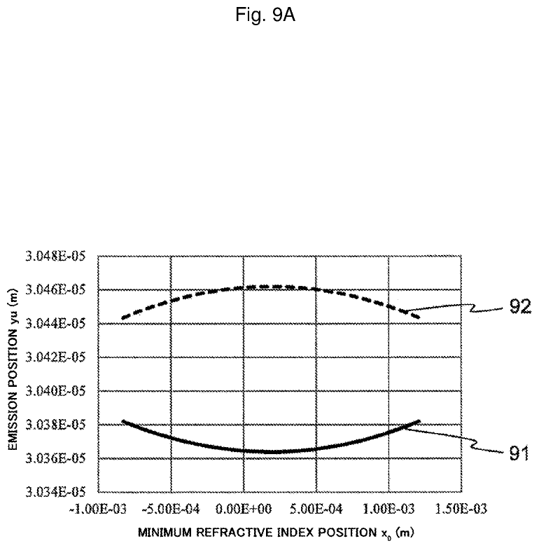

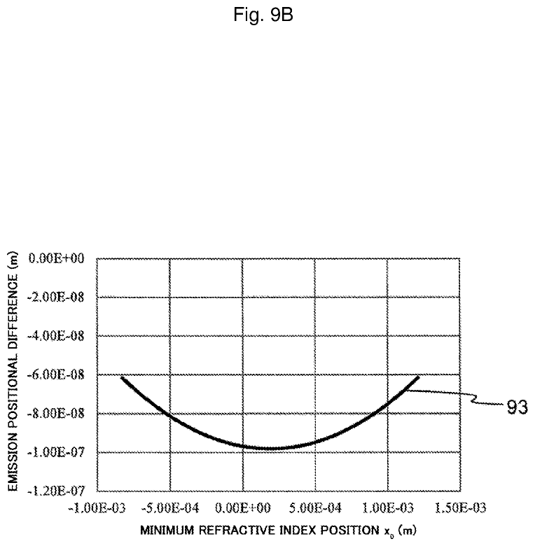

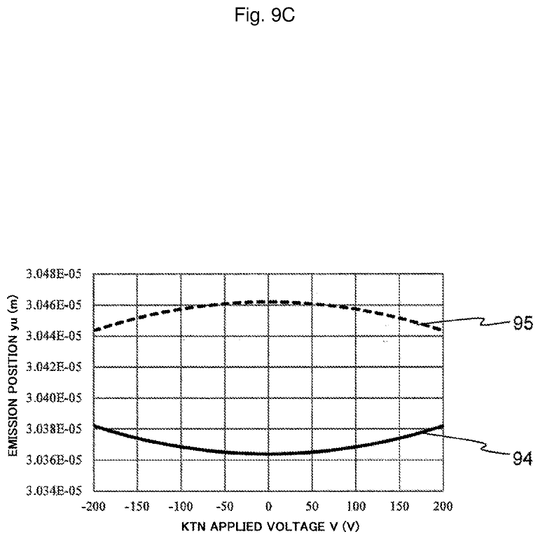

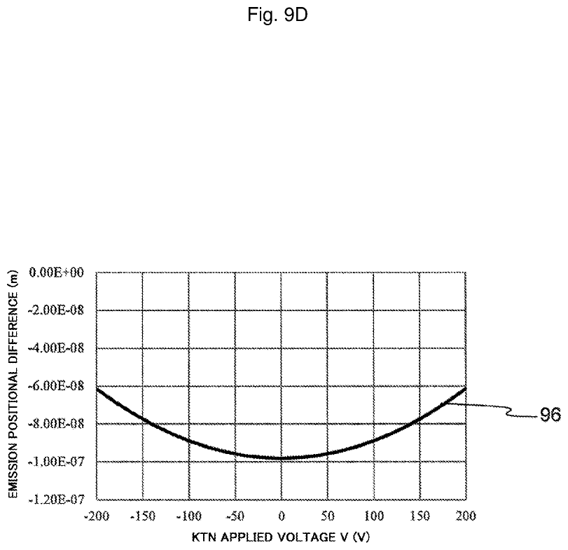

FIG. 9A shows a plot 91 obtained by plotting the position y₀ at which light incident on (x, y)=(0, 0) at an incident angle of 10° is emitted at the KTN crystal quadratic function refractive index distribution etalon 50, with respect to the minimum refractive index position x₀. Since the light is made incident on (x, y)=(0, 0), the emission position in the y-axis direction (the value of the vertical axis in FIG. 9A) becomes the amount of lateral shift of the etalon.

For comparison, a plot 92 of the emission position yᵤ₀ of the uniform refractive index distribution etalon is also shown.

Here, the emission position yᵤ₀ is calculated by converting the refractive index so that the optical path in the uniform refractive index distribution etalon becomes equal to the optical path in the quadratic function refractive index distribution etalon 50. In this calculation process, the position at which the refractive index becomes minimum is plotted as x₀.

FIG. 9B shows a plot 93 of a difference in the amount of lateral shift, y₀−yᵤ₀, between the emission position y₀ of the KTN crystal quadratic function refractive index distribution etalon 50 in FIG. 9A and the emission position yᵤ₀ of the uniform refractive index distribution etalon. According to the expression (46), as the AC voltage V varies between −200 and +200V, x₀ changes (moves) between −8.29396623×10⁻⁴ and +1.20939662×10⁻³ m. In any range of x₀, y₀−yᵤ₀ results in a negative amount, and y₀<yᵤ₀ is established, that is, the amount of lateral shift is smaller in the KTN crystal quadratic function refractive index distribution etalon 50.

FIGS. 9C and 9D are graphs in which the minimum refractive index minimum position x₀ on the horizontal axes of FIGS. 9A and 9B is replaced with the KTN applied voltage V. FIG. 9C shows a plot 95 obtained by plotting the position y₀ at which light is emitted at the KTN crystal quadratic function refractive index distribution etalon 50 and the emission position yᵤ₀ of the uniform refractive index distribution etalon. FIG. 9D shows a plot 96 of the difference in the amount of lateral shift y₀−yᵤ₀. As described above, y₀<yᵤ₀ is established in the range where V is −200 to +200, that is, the amount of lateral shift is smaller in the KTN crystal quadratic function refractive index distribution etalon 50.

The above calculation results show that it is possible to realize the refractive index distribution that suppress the lateral shift of the light transmitted through the etalon, by applying a voltage to the KTN crystal using the KTN crystal.

Next is described a calculation result regarding a change in the filter characteristics (change in the wavelength) of the KTN crystal quadratic function refractive index distribution etalon 50 that is caused by a change in the voltage V applied to the KTN. The calculation was carried out based on the expression (49).

$$\begin{matrix}Math . 51 & \\ L ≅ \frac{{n}_{o}}{2} [ \begin{matrix}( d - {x}_{0} ) \cdot \sqrt{2 {β ( d - {x}_{0} )}^{2} + [ 1 + {( β \cdot {C}_{1} )}^{2} ]} + \\ {x}_{0} \cdot \sqrt{2 β {x}_{0}^{2} + [ 1 + {( β \cdot {C}_{1} )}^{2} ]} + \frac{1 + {( β \cdot {C}_{1} )}^{2}}{\sqrt{2 β}} \cdot \\ ln ( \frac{\sqrt{2 β \cdot {( d - {x}_{0} )}^{2} + [ 1 + {( β \cdot {C}_{1} )}^{2} ]} + \sqrt{2 β} \cdot ( d - {x}_{0} )}{\sqrt{2 β \cdot {x}_{0}^{2} + [ 1 + {( β \cdot {C}_{1} )}^{2} ]} + \sqrt{2 β} \cdot {x}_{0}} )\end{matrix} ] & ( 49 )\end{matrix}$$

$$Where {x}_{0} = \frac{d}{2} - \frac{{ε}_{r} {ε}_{0} V}{ρ d}$$

$$F S {R}_{v} = \frac{c}{2 L}$$

Where c is the speed of light.

v_{q}=q·FSRᵥ
Where q is an order.

When the AC voltage V applied to the KTN is changed within the range of −200 to +200 V, the optical path length in the etalon is changed as shown in FIG. 10A. As the optical path length changes, the FSR changes as shown in FIG. 10B, and the frequency of the longitudinal mode, that is, the wavelength, changes as shown in FIG. 10C. Here, the frequency of the longitudinal mode is the frequency of the longitudinal mode of (one) q-th order (1073rd order) longitudinal mode.

In this manner, in the KTN crystal quadratic function refractive index distribution etalon 50, by changing the voltage applied to the KTN, the filter characteristics of the etalon (the frequency of the longitudinal mode) can be changed.

In other words, in an etalon using a KTN crystal having a refractive index distribution for suppressing lateral shift of light transmitted through the etalon, since the filter characteristics of the etalon (the frequency of the longitudinal mode) can be changed by changing the voltage applied to the KTN, the filter can be used as a wavelength variable filter that can be driven by a voltage or a wavelength sweep filter.

For example, if a direct-current (DC) voltage or an AC voltage of a low frequency (approximately 10 to 20 kHz or less) is applied but no high frequency AC voltage is applied, the minimum refractive index position x₀ does not change and the optical path does not change either. Therefore, the wavelength does not fluctuate with time and can be used as a wavelength variable filter.

For example, if an AC voltage of a frequency higher than 10 to 20 kHz is applied in addition to a direct-current (DC) voltage or an AC voltage of a low frequency (approximately 10 to 20 kHz or less), the minimum refractive index position x₀ changes, and the optical path also changes. Therefore, the wavelength can be continuously changed (swept) over in time, and can be used as a wavelength sweep filter.

Thus, the wavelength variable filter or the wavelength sweep filter using the KTN crystal quadratic function refractive index distribution etalon 50 has good wavelength stability (controllability).

Here, the (1073rd order) longitudinal mode shown in FIG. 10(c) represents the longitudinal mode order corresponding to a wavelength of 1550 nm. This wavelength is a wavelength used in LiDAR or the like.

Although the present embodiment has described an example of using a KTN crystal as a material having a quadratic function refractive index distribution of an etalon, KLTN (K_{1-y}L_{y}TaₓNb₁₋ₓO₃) may be used.

### Fifth Embodiment

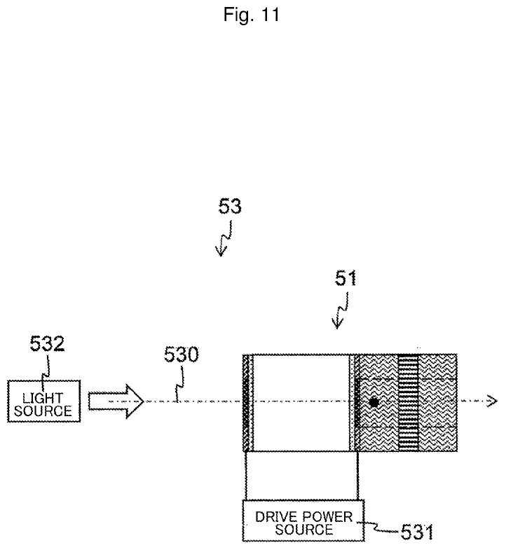

Next, an etalon device according to a fifth embodiment of the present invention will be described with reference to FIG. 11.

As shown in FIG. 11, an etalon device 53 according to the present embodiment includes the etalon 51 according to the second embodiment, a drive power source 531, and a light irradiation mechanism. As described above, the etalon 51 according to the second embodiment includes the KTN crystal quadratic function refractive index distribution etalon 50.

As a light source 532 in the light irradiation mechanism, an LED (Light Emitting Diode) is used, and the light emission wavelength is 405 nm (3.06 eV). Since the LED of this wavelength is inexpensive and commercially available, the light irradiation mechanism can be manufactured at a low cost. In addition to the light source 532, optical components such as a lens and a filter may be used for the light irradiation mechanism.

When the KTN crystal quadratic function refractive index distribution etalon 50 is operated by injecting charges (electrons) into the KTN crystal quadratic function refractive index distribution etalon 50, a direct-current (DC) voltage or an AC voltage of a low frequency (approximately 10 to 20 kHz or less) is applied between the electrodes of the KTN crystal by the drive power source 531. However, if charges (electrons) are not injected into the KTN crystal and are accumulated in the vicinity of the negative electrode, the etalon does not operate well.

In the etalon device 53 according to the present embodiment, the light source 532 irradiates the KTN crystal with light of a wavelength having a photon energy close to the band gap of 3.18 eV of the KTN crystal, and the charges (electrons) trapped in the trap level in the KTN crystal are excited and transitioned to the propagation band, whereby charges (electrons) can be injected to the vicinity of the positive electrode.

Here, the light radiated from the light source 532 is irradiated on the same optical axis 530 as the light incident on the etalon 50. The light may be radiated through the holes 515 formed in the etalon 51. The irradiation light is not limited thereto, but may be radiated from a direction different from the optical axis of the incident light, or may be radiated onto the etalon.

Here, the charge (electron) density ρ in the KTN crystal changes in accordance with the power density radiated from the light source 531. More specifically, the absolute value of ρ is small when the power density of the LED irradiation light is large, and the absolute value of ρ is large when the power density is small. The power density radiated from the light source 531 is preferably approximately 1 mW/mm² to 20 mW/mm².

When the etalon device 53 according to the present embodiment is used as a wavelength variable filter, and the wavelength is not varied with time, a DC voltage can be continuously applied to the KTN crystal while radiating the KTN crystal with light having a photon energy close to 3.18 eV (for example, a wavelength of 405 nm).

When the etalon device 53 according to the present embodiment is used as a wavelength sweep filter and the wavelength is changed (swept) continuously with time, a voltage obtained by superimposing an alternating-current (AC) voltage on a DC voltage can be applied to the KTN crystal while irradiating light having a photon energy close to 3.18 eV (for example, a wavelength of 405 nm). In this case, the frequency of the AC voltage is preferably high (10 kHz or higher) so that charge injection into the KTN crystal does not occur.

The present embodiment has described an example in which the light emitting wavelength of the light source is 405 nm, but the present invention is not limited thereto, and other wavelengths may be used. The wavelength may be any wavelength capable of exciting the charges (electrons) trapped at the trap level in the KTN crystal in the propagation band.

Although the etalon 51 according to the second embodiment is used in the present embodiment, the etalon 52 according to the second embodiment may be used. In this case, the irradiation light is radiated through the holes 515 or holes 527 formed in the etalon 52.

The embodiments according to the present invention have described an example in which a semi-reflecting mirror is used, but the present invention is not limited thereto, and a semi-reflecting mirror may does not have to be used. Even if a semi-reflecting mirror is not used, if the refractive index of the etalon is different from the refractive index of the periphery of the etalon, such as air, the light is reflected on the surface of the etalon by Fresnel reflection, thereby achieving the same effects.

The embodiments of the present invention have described an example in which the refractive index of the dielectric used in the etalon varies by a quadratic function, but the present invention is not limited thereto. The refractive index distribution of the dielectric used in the etalon according to the embodiments of the present invention may be set so that the lateral shift is smaller than that of the uniform refractive index distribution etalon under the condition that the optical path length of the light transmitted through the etalon is equal to that of the uniform refractive index distribution etalon.

When comparing the lateral shifts, the lateral shift of the etalon and the lateral shift of the uniform refractive index distribution etalon according to the embodiments of the present invention may be expressed by an incident angle of light transmitted through the etalon from the outside.

For example, the refractive index may vary so as to be downwardly convex in the refractive index distribution. For example, the refractive index may decrease from one end surface of the dielectric used in the etalon toward the inside of the dielectric, and increase from an arbitrary point inside the dielectric to the other end surface. Further, the change in the refractive index of the dielectric may be monotonously decreased or monotonously increased.

The embodiments of the present invention have described an example in which the refractive index inside the etalon varies in the x-axis direction and does not vary in the y-axis direction, but the present invention is not limited thereto. The refractive index inside the etalon may vary in the y-axis direction.

The embodiments according to the present invention have described an example in which a KTN crystal is used as a dielectric of an etalon, but the present invention is not limited thereto. Barium titanate (BaTiO₃: BT), potassium tantalate (KTaO₃: KT), or strontium titanate (SrTiO₃: ST) may be used as a substance that exhibits the Kerr effect, which is an electro-optic effect.

Further, a substance having a Pockel's effect where the refractive index changes in proportion to the applied voltage may be used as the dielectric used for the etalon. As the substance that has the Pockel's effect, lithium niobate (LiNbO₃; hereinafter abbreviated as “LN”) may be used, or lead lanthanum zirconate titanate ((Pb₁₋ₓLaₓ) (Zr_{y} Ti_{1-y})₁₋ₓ/4O₃: PLZT)) may also be used.

The embodiments according to the present invention have described an example in which a KTN crystal is used as an etalon and the refractive index is changed by applying a voltage from the outside, but the present invention is not limited thereto. The refractive index may be changed by changing components and compositions in the dielectric. In this case, even if SiOₓ, SiNₓ, SiOₓN_{y} or the like is used in addition to the above-mentioned substances, the compositions x and y may be changed.

The embodiments of the present invention have described examples of structures, sizes, materials, and the like of the constituent components, with respect to the configurations of the etalon and the etalon device, as well as the manufacturing method thereof, but the present invention is not limited thereto. The functions of the etalon and the etalon device may be exerted to achieve the effects thereof.

### INDUSTRIAL APPLICABILITY

The present invention can be applied to a wavelength selection filter or an interference filter for narrowing a wavelength band, as an optical filter in the field of wavelength multiplexing (WDM) transmission optical communication, precision measurement, and the like.

### REFERENCE SIGNS LIST

10 etalon
20 Uniform refractive index distribution etalon

1. An etalon in which light is made incident from a direction different from a direction perpendicular to an incident surface and is emitted from an emission surface facing the incident surface, the etalon comprising a dielectric that has a first end surface on the incident surface side and a second end surface on the emission surface side so as to oppose the first end surface, wherein a refractive index distribution of the dielectric is set in such a manner that a lateral shift of the light becomes smaller between the first end surface and the second end surface as compared with a uniform refractive index distribution etalon under a condition that an optical path length of the light is equal.

2. An etalon in which light is made incident from a direction different from a direction perpendicular to an incident surface and is emitted from an emission surface facing the incident surface, the etalon comprising a dielectric that has a first end surface on the incident surface side and a second end surface on the emission surface side so as to oppose the first end surface, wherein a refractive index of the dielectric changes by a quadratic function of x when a distance in a vertical direction from the first end surface toward the second end surface is x.

3. (canceled)

4. The etalon according to claim 1, further comprising a temperature adjustment mechanism.

5. An etalon device, comprising the etalon according claim 1, a drive power source, and a light source, wherein the light source emits light onto the etalon.

6. A method for controlling an etalon in which light is made incident from a direction different from a direction perpendicular to an incident surface and is emitted from an emission surface facing the incident surface, the etalon comprising a dielectric having a first end surface on the incident surface side and a second end surface on the emission surface side so as to oppose the first end surface, wherein the method comprises the steps of: applying a voltage between the first end surface and the second end surface to change a refractive index of the dielectric between the first end surface and the second end surface; and reducing a distance between a point on the emission surface from which the light is emitted and a point on the emission surface where the light is incident from the direction perpendicular to the incident surface and emitted.

7. The method for controlling an etalon according to claim 6, further comprising the step of irradiating the etalon with irradiation light.

8. (canceled)

9. The etalon according to claim 2, further comprising a temperature adjustment mechanism.

10. An etalon device, comprising the etalon according to claim 2, a drive power source, and a light source, wherein the light source emits light onto the etalon.

11. An etalon device, comprising the etalon according to claim 4, a drive power source, and a light source, wherein the light source emits light onto the etalon.
